(19) United States
(12) Patent Application Publication
(10) Pub. No.: US 2023/0157040 A1
(43) Pub. Date: May 18, 2023

(54) PHOTOELECTRIC CONVERSION ELEMENT AND IMAGING DEVICE

(71) Applicant: Sony Group Corporation, Tokyo (JP)

(72) Inventors: Yosuke MURAKAMI, Tokyo (JP); Masato KANNO, Tokyo (JP); Miki KIMIJIMA, Tokyo (JP)

(21) Appl. No.: 18/010,732

(22) PCT Filed: Jun. 10, 2021
(86) PCT No.: PCT/JP2021/022192

§ 371 Date: Dec. 15, 2022

(30) Foreign Application Priority Data
Jun. 19, 2020 (JP) 2020-106510

(51) Int. Cl. H10K 39/32

(52) U.S. Cl. CPC H10K 39/32

(57) ABSTRACT

A photoelectric conversion element of an embodiment of the present disclosure includes: a first electrode; a second electrode disposed to be opposed to the first electrode; and an organic photoelectric conversion layer provided between the first electrode and the second electrode, the organic photoelectric conversion layer having, in the layer, a domain being larger than 1 nm and smaller than 10 nm and including one organic semiconductor material in a predetermined cross-section between the first electrode and the second electrode.

### TECHNICAL FIELD

The present disclosure relates to a photoelectric conversion element using an organic semiconductor material and an imaging device including the photoelectric conversion element.

### BACKGROUND ART

For example, PTL 1 discloses a photoelectric conversion element with improved external quantum efficiency and response speed, which is achieved by providing an organic photoelectric conversion layer having, in the layer, a percolation structure that traverses vertically in a film thickness direction and having a domain of which a domain length in a planar direction is smaller than a domain length in the film thickness direction.

### CITATION LIST

### Patent Literature

PTL 1: International Publication No. WO2019/098315

### SUMMARY OF THE INVENTION

Thus, a photoelectric conversion element using an organic semiconductor material is required to have improved response characteristics.

It is desirable to provide a photoelectric conversion element and an imaging device that make it possible to improve response characteristics.

A photoelectric conversion element of an embodiment of the present disclosure includes: a first electrode; a second electrode disposed to be opposed to the first electrode; and an organic photoelectric conversion layer provided between the first electrode and the second electrode, the organic photoelectric conversion layer having, in the layer, a domain being larger than 1 nm and smaller than 10 nm and including one organic semiconductor material in a predetermined cross-section between the first electrode and the second electrode.

An imaging device of an embodiment of the present disclosure includes pixels, each of which includes one or multiple organic photoelectric conversion sections, and includes the photoelectric conversion element of an embodiment of the present disclosure as the one or the multiple organic photoelectric conversion sections.

In the photoelectric conversion element of an embodiment of the present disclosure and the imaging device of an embodiment of the present disclosure, the organic photoelectric conversion layer is provided that has a domain being larger than 1 nm and smaller than 10 nm and including one organic semiconductor material in a predetermined cross-section between the first electrode and the second electrode. This improves movement of electric charges having undergone charge separation in the organic photoelectric conversion layer.

### BRIEF DESCRIPTION OF THE DRAWINGS

FIG. 1 is a schematic cross-sectional view of an example of a configuration of a photoelectric conversion element according to an embodiment of the present disclosure.

FIG. 2 is a schematic planar view of a configuration of a unit pixel of the photoelectric conversion element illustrated in FIG. 1.

FIG. 3 is a model diagram of a crystal of one organic semiconductor material as viewed in a direction of [301].

FIG. 4 is a model diagram of the crystal of the one organic semiconductor material as viewed in in a direction of [20-1].

FIG. 5 is a schematic cross-sectional view of another example of the configuration of the photoelectric conversion element according to an embodiment of the present disclosure.

FIG. 6 is an explanatory schematic cross-sectional view of a method of manufacturing the photoelectric conversion element illustrated in FIG. 1.

FIG. 7 is a schematic cross-sectional view of a step subsequent to FIG. 6.

FIG. 8 is a schematic cross-sectional view of an example of a configuration of a photoelectric conversion element according to Modification Example 1 of the present disclosure.

FIG. 9 is an equivalent circuit diagram of the photoelectric conversion element illustrated in FIG. 8.

FIG. 10 is a schematic view of arrangement of transistors constituting a control section of the photoelectric conversion element and a lower electrode of an organic photoelectric conversion section illustrated in FIG. 8.

FIG. 11 is a timing diagram illustrating an operation example of the photoelectric conversion element illustrated in FIG. 8.

FIG. 12 is a schematic cross-sectional view of an example of a configuration of a photoelectric conversion element according to Modification Example 2 of the present disclosure.

FIG. 13A is a schematic cross-sectional view of an example of a configuration of a photoelectric conversion element according to Modification Example 3 of the present disclosure.

FIG. 13B is a schematic planar view of an example of a pixel configuration of an imaging device including the photoelectric conversion element illustrated in FIG. 13A.

FIG. 14A is a schematic cross-sectional view of an example of a configuration of a photoelectric conversion element according to Modification Example 4 of the present disclosure.

FIG. 14B is a schematic planar view of an example of a pixel configuration of an imaging device including the photoelectric conversion element illustrated in FIG. 14A.

FIG. 15 is a block diagram illustrating an overall configuration of an imaging device including the photoelectric conversion element illustrated in FIG. 1, etc.

FIG. 16 is a functional block diagram illustrating an example of an electronic apparatus using the imaging device illustrated in FIG. 15.

FIG. 17 is a block diagram depicting an example of a schematic configuration of an in-vivo information acquisition system.

FIG. 18 is a view depicting an example of a schematic configuration of an endoscopic surgery system.

FIG. 19 is a block diagram depicting an example of a functional configuration of a camera head and a camera control unit (CCU).

FIG. 20 is a block diagram depicting an example of schematic configuration of a vehicle control system.

FIG. 21 is a diagram of assistance in explaining an example of installation positions of an outside-vehicle information detecting section and an imaging section.

FIG. 22 is a schematic cross-sectional view of a configuration of a device sample used in Experimental Examples 1 to 3.

FIG. 23 is a schematic cross-sectional view of a configuration of a domain confirmation sample used in Experimental Examples 1 to 3.

FIG. 24A is an explanatory schematic view of a manufacturing step of a planar observation sample by means of FIB.

FIG. 24B is a schematic view of a step subsequent to FIG. 24A.

FIG. 24C is a schematic view of a step subsequent to FIG. 24B.

FIG. 25 is a schematic view of a step subsequent to FIG. 24C.

FIG. 26 is an explanatory schematic view of a working method for the domain confirmation sample.

FIG. 27 is a schematic view of a step subsequent to FIG. 26.

FIG. 28 is a schematic view of a TEM image of Experimental Example 1.

FIG. 29 is a schematic view of a TEM image of Experimental Example 2.

FIG. 30 is a schematic view of a TEM image of Experimental Example 3.

FIG. 31 is a diagram illustrating results of X-ray diffraction of Experimental Examples 1 to 3.

FIG. 32 is a diagram illustrating a distance between crystal domains of Experimental Example 1.

FIG. 33 is a diagram illustrating a distance between crystal domains of Experimental Example 2.

FIG. 34 is a diagram illustrating a distance between crystal domains of Experimental Example 3.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. Embodiment (An example of providing an organic photoelectric conversion layer having a domain of 1 nm or more and 10 nm or less in a predetermined cross-section)
   1-1. Configuration of Photoelectric Conversion Element
   1-2. Method of Manufacturing Photoelectric Conversion Element
   1-3. Workings and Effects
2. Modification Examples
   2-1. Modification Example 1 (An example in which a lower electrode includes multiple electrodes)
   2-2. Modification Example 2 (An example of a photoelectric conversion element in which multiple organic photoelectric conversion sections are stacked)
   2-3. Modification Example 3 (An example of a photoelectric conversion element that performs dispersion for an inorganic photoelectric conversion section using a color filter)
   2-4. Modification Example 4 (An example of a photoelectric conversion element that performs dispersion for an inorganic photoelectric conversion section using a color filter)
3. Application Examples
4. Practical Application Examples
5. Examples

### 1. Embodiment

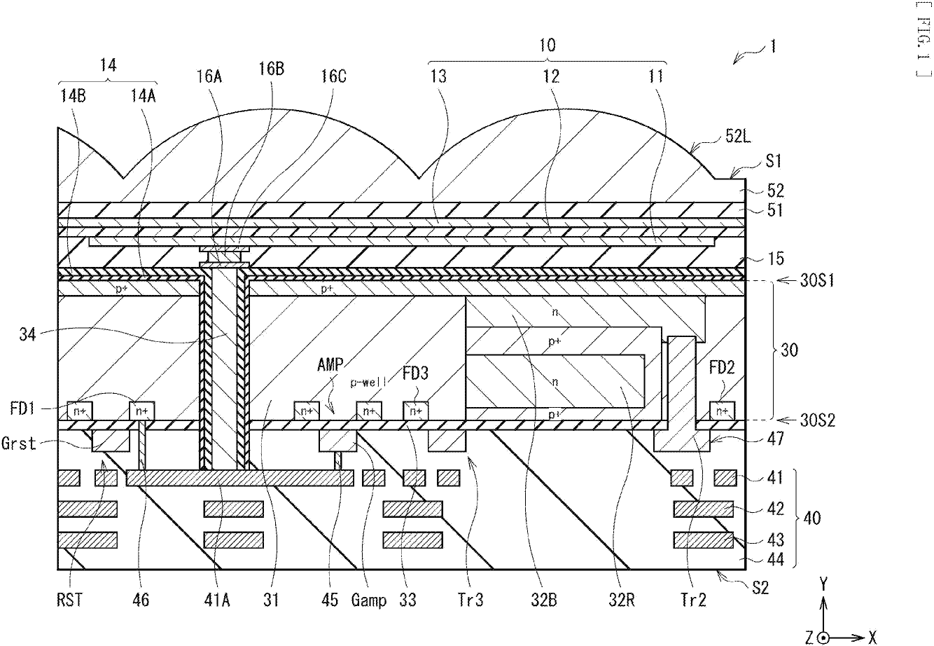

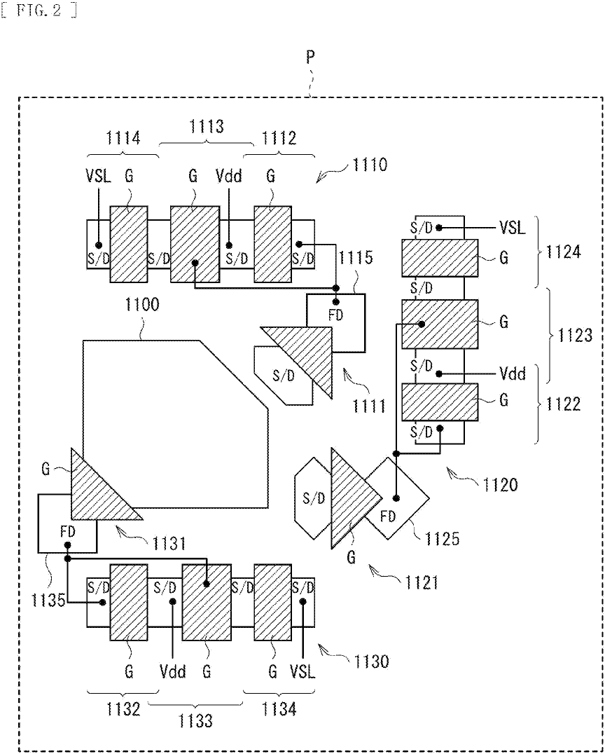

FIG. 1 illustrates an example of a cross-sectional configuration of a photoelectric conversion element (a photoelectric conversion element 1) according to an embodiment of the present disclosure. FIG. 2 illustrates an example of a planar configuration of the photoelectric conversion element 1 illustrated in FIG. 1. The photoelectric conversion element 1 constitutes one pixel (a unit pixel P) in an imaging device (an imaging device 100) such as a CMOS (Complementary Metal Oxide Semiconductor) image sensor to be used, for example, in an electronic apparatus such as a digital still camera or a video camera (see FIG. 15). The photoelectric conversion element 1 includes, for example, an organic photoelectric conversion section 10 in which a lower electrode 11, an organic photoelectric conversion layer 12, and an upper electrode 13 are stacked in this order. The photoelectric conversion element 1 of the present embodiment has a configuration in which the organic photoelectric conversion layer 12 constituting the organic photoelectric conversion section 10 has, in a predetermined cross-section, a domain larger than 1 nm and smaller than 10 nm including one organic semiconductor material.

### 1-1. Configuration of Photoelectric Conversion Element

The photoelectric conversion element 1 is a so-called vertical spectroscopic photoelectric conversion element in which one organic photoelectric conversion section 10 and two inorganic photoelectric conversion sections 32B and 32R are stacked in a vertical direction, for each unit pixel P. The organic photoelectric conversion section 10 is provided on a side of a back surface (a first surface 30S1) of a semiconductor substrate 30. The inorganic photoelectric conversion sections 32B and 32R are each formed to be embedded in the semiconductor substrate 30, and are stacked in a thickness direction of the semiconductor substrate 30.

The organic photoelectric conversion section 10 and the inorganic photoelectric conversion sections 32B and 32R selectively detect light beams of different wavelength bands and perform photoelectric conversion. For example, the organic photoelectric conversion section 10 acquires a color signal of green (G). The inorganic photoelectric conversion sections 32B and 32R acquire color signals of blue (B) and red (R), respectively, depending on differences in absorption coefficients. This enables the photoelectric conversion element 1 to acquire multiple types of color signals in one pixel without using a color filter.

It is to be noted that description is given, for the photoelectric conversion element 1, of a case of reading holes, among electron-hole pairs generated by photoelectric conversion, as signal charges (a case of adopting a p-type semiconductor region as a photoelectric conversion layer). In addition, in the diagram, “+ (plus)” attached to “p” and “n” indicates that p-type or n-type impurity concentration is high.

The semiconductor substrate 30 is configured by, for example, an n-type silicon (Si) substrate, and includes a p-well 31 in a predetermined region. A second surface (a front surface of the semiconductor substrate 30) 30S2 of the p-well 31 is provided with, for example, various floating diffusions (floating diffusion layers) FD (e.g., FD1, FD2, and FD3), various transistors Tr (e.g., a vertical transistor (transfer transistor) Tr2, a transfer transistor Tr3, an amplifier transistor (modulation element) AMP, and a reset transistor RST), and a multilayer wiring layer 40. The multilayer wiring layer 40 has a configuration in which, for example, wiring layers 41, 42, and 43 are stacked in an insulating layer 44. In addition, a peripheral part of the semiconductor substrate 30 is provided with a peripheral circuit (unillustrated) including a logic circuit or the like.

It is to be noted that, in FIG. 1, the side of the first surface 30S1 of the semiconductor substrate 30 is denoted by a light incident side S1, and a side of the second surface 30S2 thereof is denoted by a wiring layer side S2.

The organic photoelectric conversion section 10 has a configuration in which the lower electrode 11, the organic photoelectric conversion layer 12, and the upper electrode 13 are stacked in this order, and the organic photoelectric conversion layer 12 has, in the layer, a bulk hetero junction structure. The bulk hetero junction structure is a p/n junction surface formed by mixing a p-type semiconductor and a n-type semiconductor together.

The inorganic photoelectric conversion sections 32B and 32R are configured by, for example, a PIN (Positive Intrinsic Negative) type photodiode, and each thereof has a p-n junction in a predetermined region of the semiconductor substrate 30. The inorganic photoelectric conversion sections 32B and 32R enable light to be dispersed in the vertical direction by utilizing a difference in wavelength bands to be absorbed depending on incidence depth of light in the silicon substrate.

The inorganic photoelectric conversion section 32B selectively detects blue light and accumulates signal charges corresponding to a blue color; the inorganic photoelectric conversion section 32B is installed at a depth at which the blue light is able to be efficiently subjected to photoelectric conversion. The inorganic photoelectric conversion section 32R selectively detects red light and accumulates signal charges corresponding to a red color; the inorganic photoelectric conversion section 32R is installed at a depth at which the red light is able to be efficiently subjected to photoelectric conversion. It is to be noted that blue (B) is a color corresponding to a wavelength band of 450 nm or more and less than 495 nm, for example, and red (R) is a color corresponding to a wavelength band of 620 nm or more and less than 750 nm, for example. It is sufficient for each of the inorganic photoelectric conversion sections 32B and 32R to be able to detect light of a portion or all of each wavelength band.

Specifically, as illustrated in FIG. 1, each of the inorganic photoelectric conversion section 32B and the inorganic photoelectric conversion section 32R includes, for example, a p+ region serving as a hole accumulation layer and an n region serving as an electron accumulation layer (having a p-n-p stacked structure). The n region of the inorganic photoelectric conversion section 32B is coupled to the vertical transistor Tr2. The p+ region of the inorganic photoelectric conversion section 32B bends along the vertical transistor Tr2, and is linked to the p+ region of the inorganic photoelectric conversion section 32R.

The vertical transistor Tr2 is a transfer transistor that transfers, to a floating diffusion FD2, the signal charges corresponding to the blue color generated and accumulated in the inorganic photoelectric conversion section 32B. The inorganic photoelectric conversion section 32B is formed at a deep position from the second surface 30S2 of the semiconductor substrate 30, and thus the transfer transistor of the inorganic photoelectric conversion section 32B is preferably configured by the vertical transistor Tr2.

The transfer transistor Tr3 transfers, to a floating diffusion FD3, the signal charges corresponding to the red color generated and accumulated in the inorganic photoelectric conversion section 32R, and is configured by, for example, a MOS transistor.

The amplifier transistor AMP is, for example, a modulation element that modulates an amount of electric charges generated in the organic photoelectric conversion section 10, and is configured by, for example, a MOS transistor.

The reset transistor RST resets, for example, electric charges transferred from the organic photoelectric conversion section 10 to a floating diffusion FD1, and is configured by, for example, a MOS transistor.

Interlayer insulating layers 14 and 15 are stacked in this order, for example, from a side of the semiconductor substrate 30 between the first surface 30S1 of the semiconductor substrate 30 and the lower electrode 11. The interlayer insulating layer 14 has a configuration in which, for example, a layer having a fixed charge (fixed charge layer) 14A and a dielectric layer 14B having an insulating property are stacked. A protective layer 51 is provided on the upper electrode 13. An on-chip lens layer 52, which configures an on-chip lens 52L and serves also as a planarization layer, is disposed above the protective layer 51.

A through-electrode 34 is provided between the first surface 30S1 and the second surface 30S2 of the semiconductor substrate 30. The organic photoelectric conversion section 10 is coupled to a gate Gamp of the amplifier transistor AMP and the floating diffusion FD1 via the through-electrode 34. This makes it possible for the photoelectric conversion element 1 to favorably transfer electric charges (holes) generated in the organic photoelectric conversion section 10 on the side of the first surface 30S1 of the semiconductor substrate 30 to the side of the second surface 30S2 of the semiconductor substrate 30 via the through-electrode 34, and thus to enhance the characteristics.

The through-electrode 34 is provided for each unit pixel P, for example. The through-electrode 34 functions as a connector between the organic photoelectric conversion section 10 and the gate Gamp of the amplifier transistor AMP as well as the floating diffusion FD1, and serves as a transmission path for electric charges generated in the organic photoelectric conversion section 10.

The lower end of the through-electrode 34 is coupled to, for example, a coupling section 41A in the wiring layer 41, and the coupling section 41A and the gate Gamp of the amplifier transistor AMP are coupled to each other via a lower first contact 45. The coupling section 41A and the floating diffusion FD1 are coupled to the lower electrode 11 via a lower second contact 46. It is to be noted that, in FIG. 1, the through-electrode 34 is illustrated to have a cylindrical shape, but this is not limitative; the through-electrode 34 may also have a tapered shape, for example.

As illustrated in FIG. 1, a reset gate Grst of the reset transistor RST is preferably disposed next to the floating diffusion FD1. This makes it possible to reset electric charges accumulated in the floating diffusion FD1 by the reset transistor RST.

In the photoelectric conversion element 1 of the present embodiment, light incident on the organic photoelectric conversion section 10 from the light incident side S1 is absorbed by the organic photoelectric conversion layer 12. Excitons thus generated move to an interface between an electron donor and an electron acceptor constituting the organic photoelectric conversion layer 12, and undergo exciton separation, i.e., dissociate into electrons and holes. The electric charges (electrons and holes) generated here are transported to different electrodes by diffusion due to a difference in carrier concentrations or by an internal electric field due to a difference in work functions between an anode (here, the lower electrode 11) and a cathode (here, the upper electrode 13), and are detected as a photocurrent. In addition, application of a potential between the lower electrode 11 and the upper electrode 13 makes it possible to control directions in which electrons and holes are transported.

In the following, description is given of configurations, materials, and the like of the respective sections constituting the photoelectric conversion element 1.

The organic photoelectric conversion section 10 is an organic photoelectric conversion element that absorbs green light corresponding to a portion or all of a selective wavelength band (e.g., 495 nm or more and less than 620 nm) to generate excitons (electron-hole pairs). In the imaging device 100 described later, for example, holes, among the electron-hole pairs generated by photoelectric conversion, are read as signal charges from a side of the lower electrode 11. In the photoelectric conversion element 1, the lower electrode 11 is formed separately for each unit pixel P, for example. The organic photoelectric conversion layer 12 and the upper electrode 13 are provided as successive layers common to multiple unit pixels P (e.g., a pixel section 100A illustrated in FIG. 11).

The lower electrode 11 is provided in a region opposed to and covering light-receiving surfaces of the inorganic photoelectric conversion sections 32B and 32R formed in the semiconductor substrate 30. The lower electrode 11 is configured by an electrically-conductive film having light transmissivity. Examples of a constituent material of the lower electrode 11 include ITO (indium tin oxide), In₂O₃ doped with tin (Sn) as a dopant, indium tin oxides including crystalline ITO and amorphous ITO. As a constituent material of the lower electrode 11, a tin oxide (SnO₂)-based material doped with a dopant or a zinc oxide-based material doped with a dopant may be used. Examples of the zinc oxide-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). In addition, CuIs, InSbO₄, ZnMgO, CuInO₂, MgIN₂O₄, CdO, ZnSnO₃, TiO₂, or the like may be used as a constituent material of the lower electrode 11. Further, a spinel-type oxide or an oxide having a YbFe₂O₄ structure may be used. It is to be noted that the lower electrode 11 formed using the material as described above typically has a high work function, and functions as an anode electrode.

The organic photoelectric conversion layer 12 converts optical energy into electric energy. The organic photoelectric conversion layer 12 absorbs light of a portion or all of wavelengths in a visible light region of 495 nm or more and less than 620 nm, for example. The organic photoelectric conversion layer 12 includes, for example, organic materials of at least two types of a p-type semiconductor and an n-type semiconductor. The n-type semiconductor is an electron-transporting material that functions relatively as an electron acceptor (acceptor), and the p-type semiconductor is a hole-transporting material that functions relatively as an electron donor (donor). The organic photoelectric conversion layer 12 provides a field in which excitons generated upon light absorption are separated into electrons and holes; specifically, excitons are separated into electrons and holes at an interface (p/n junction plane) between the electron donor and the electron acceptor.

In a case where the organic photoelectric conversion layer 12 is formed using two types of organic materials of the p-type semiconductor and the n-type semiconductor, for example, one of the p-type semiconductor or the n-type semiconductor is preferably a material having light transmissivity to visible light, and the other one thereof is preferably a material that performs photoelectric conversion of light of a selective wavelength band of a visible light region. Alternatively, the organic photoelectric conversion layer 12 may be formed using, for example, three types of organic materials of a pigment material having a local maximum absorption wavelength in a selective wavelength band (e.g., 495 nm or more and less than 620 nm in the present embodiment) of the visible light region, and the n-type semiconductor and the p-type semiconductor, which have light transmissivity to visible light. The organic photoelectric conversion layer 12 has, in the layer, a bulk hetero structure in which the multiple kinds of organic materials are randomly mixed.

In the layer of the organic photoelectric conversion layer 12 of the present embodiment, as described above, a domain larger than 1 nm and smaller than 10 nm including one organic semiconductor material is formed in a predetermined cross-section between the lower electrode 11 and the upper electrode 13. It is to be noted that the domain refers to a region in which organic materials of one kind of multiple organic materials constituting the organic photoelectric conversion layer 12 are arranged in succession. In the organic photoelectric conversion layer 12, one of the p-type semiconductor (hole-transporting material) or the n-type semiconductor (electron-transporting material) described above may form a domain, or each of the p-type semiconductor and the n-type semiconductor may form a domain.

For example, it is preferable for the domain to at least partially have a crystal property, and specifically the domain preferably includes a crystal. The domain configured by a crystal enables reduction in trapping of electric charges in the domain. Further, the component ratio of the one organic material forming a crystal in this domain is preferably 20% or more and 70% or less. Setting the component ratio of the one organic material to the above-described range allows the domains of a size larger than 1 nm and smaller than 10 nm to be dispersed in the organic photoelectric conversion layer 12.

The full width at half maximum (Full width at half maximum; FWHM) of a crystallization peak by means of X-ray diffraction (XRD) of the domain including the one organic semiconductor material is preferably 0.015 rad or more and 0.15 rad or less. The FWHM of the crystallization peak is inversely proportional to a crystal size. That is, a microcrystal has a larger FWHM. Meanwhile, also in the case of amorphous, the half-power band width becomes large because of a broad peak. Accordingly, it is difficult to determine whether it is microcrystal or amorphous only from the half-power band width. It is to be noted that “crystallization peak by means of XRD” means that a crystallization peak obtained by a single molecular crystal is broad in the present embodiment, or a case where a lattice fringe indicating the presence of a microcrystal is confirmed by a transmission electron microscope. In observation by the transmission electron microscope (Transmission Electron Microscope), observation of a smaller size requires higher observation magnification, which results in a narrower field of view for observation. This involves a disadvantage in that only spatially localized information is obtained. Obtaining information on a wider region by shooting while gradually moving the field of view for observation is not theoretically impossible. However, it is impractical to move the field of view in nm order, for example, to grasp even the extent of nm order. Meanwhile, the XRD enables obtainment of information on an average of entire samples by irradiation of the entire samples with an X-ray. Therefore, using the TEM and the XRD in combination in a complementary manner enables understanding of a local structure and an entire structure. That is, the FWHM of the crystallization peak being 0.015 rad or more means existence of the microcrystal in the entire samples.

It is to be noted that the numerical range of the FWHM of the crystallization peak described above is the one in a case of using a Cu-Kα ray as the X-ray. As for measurement of a domain size by means of the XRD, a domain observation sample is prepared to enable measurement of the domain size by means of a thin-film method using a Cu-Kα ray and a divergence slit of 1 mm, although detailed description thereof is given in Example.

Multiple domains are formed in a layer of the organic photoelectric conversion layer 12. An average cycle obtained from autocorrelation of a two-dimensional distribution of the multiple domains is preferably 3 nm or more and 5 nm or less. The autocorrelation refers to an index indicating how far away from a domain there are domains of equivalent shapes and sizes. Typically, in the case of amorphous, there is no long-range regularity as compared with an interatomic distance; meanwhile the amorphous state is no such complete chaotic state as a gas. Examples of a method for quantitatively representing the regularity of such a single range include a scale of a radial distribution function, which is typically measured by scattering of an X-ray or a neutron ray. However, the radial distribution function should be regarded as a one-dimensional distribution, and is not necessarily appropriate as a method for representing a difference between the organic photoelectric conversion layer 12 of the present embodiment and a common organic photoelectric conversion layer. Therefore, in the present embodiment, a domain distribution existing in a cross-section between the lower electrode 11 and the upper electrode 13 is grasped two-dimensionally, and an average cycle of the domains is obtained from the autocorrelation of the two-dimensional distribution to define the average cycle as 5 nm or less.

Examples of a specific material constituting the organic photoelectric conversion layer 12 include the following organic materials. Examples of the electron-transporting material include C₆₀ fullerene, C₇₀ fullerene, and derivatives thereof. It is preferable to use, as the hole-transporting material, an organic material having an ionization potential of 6 eV or less in a case of using it as an image sensor, from the viewpoint of reduction in a dark current as well as external quantum efficiency. Examples of such a hole-transporting material include a compound (BDT3) represented by the following formula (1). This BDT3 is an example of the one organic semiconductor material forming the domain described above

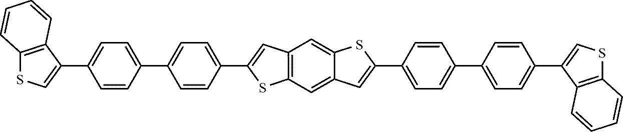 [SMILES: c1ccc2c(-c3ccc(-c4ccc(-c5cc6cc7sc(-c8ccc(-c9ccc(-c%10csc%11ccccc%10%11)cc9)cc8)cc7cc6s5)cc4)cc3)csc2c1]

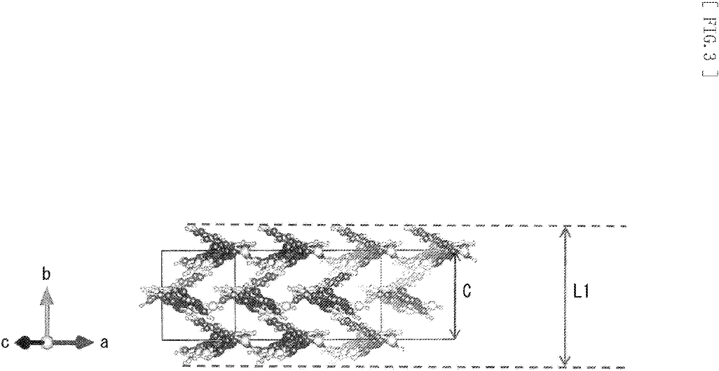

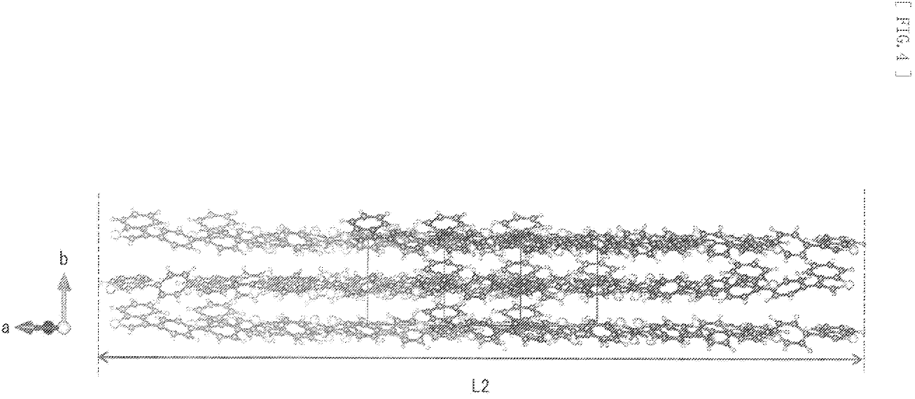

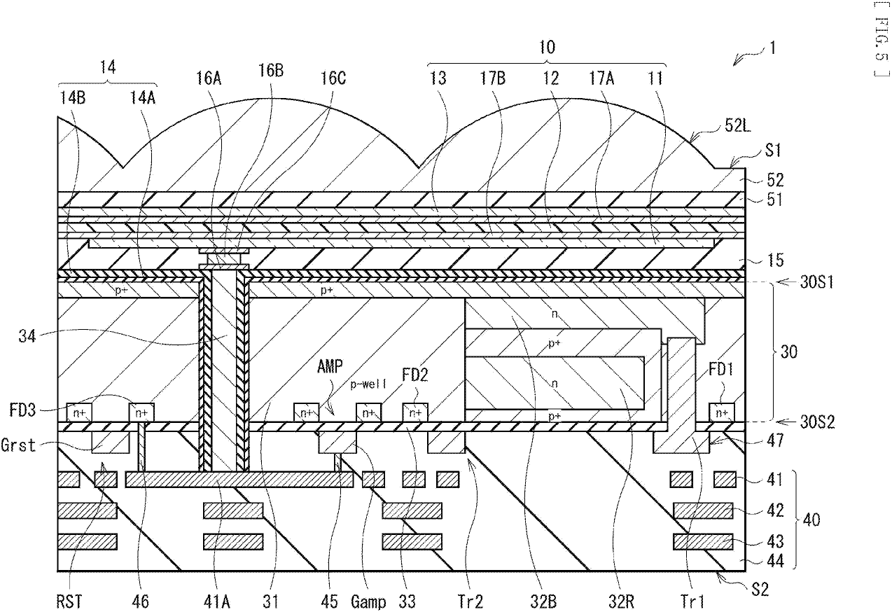

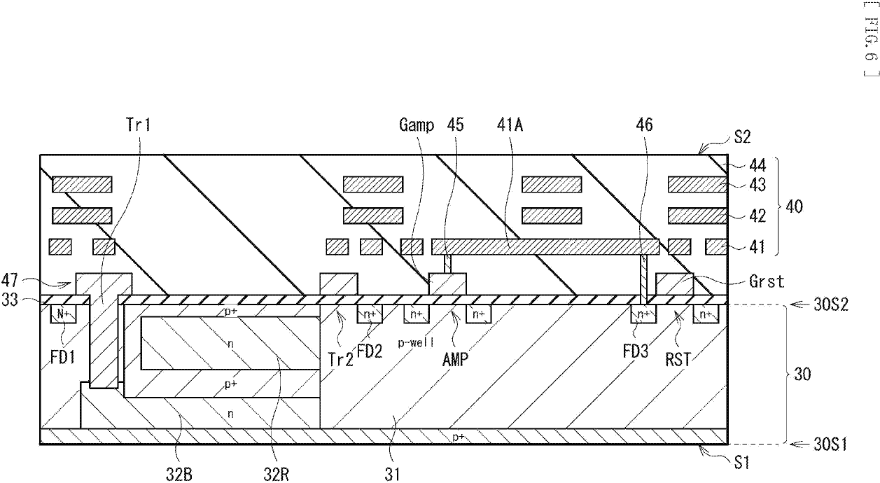

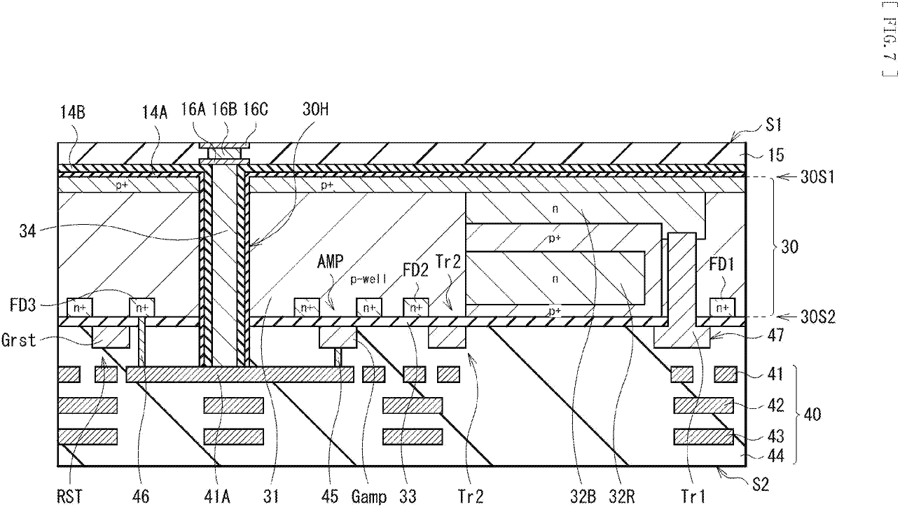

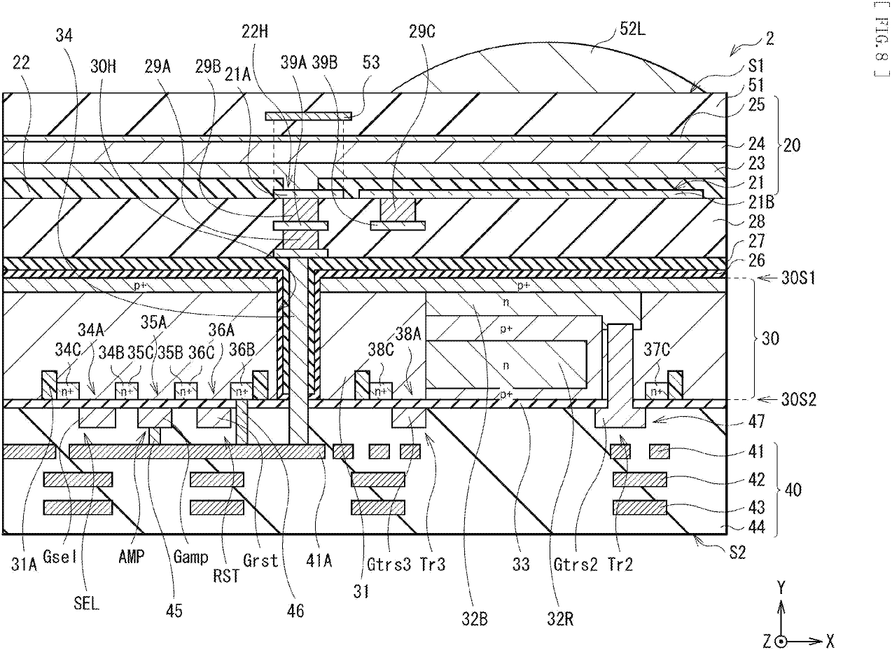

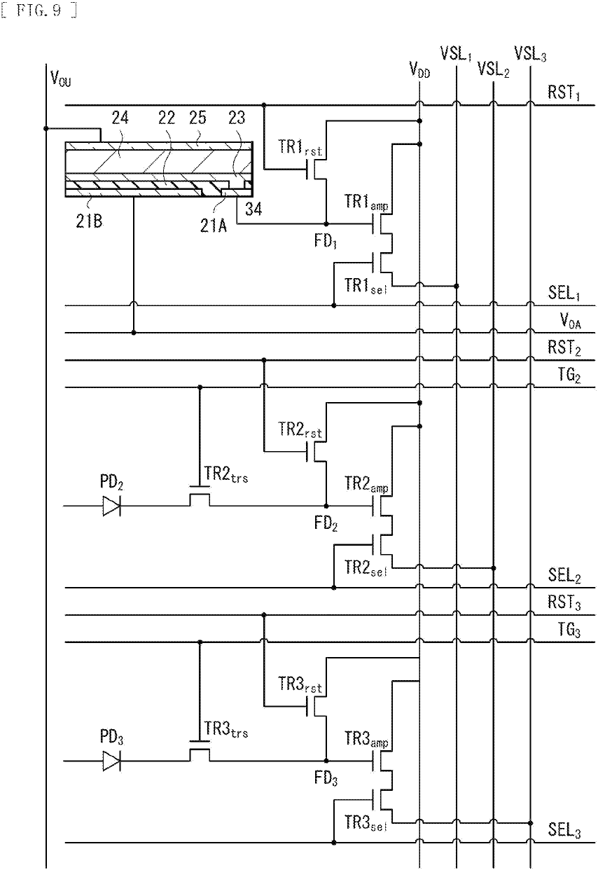

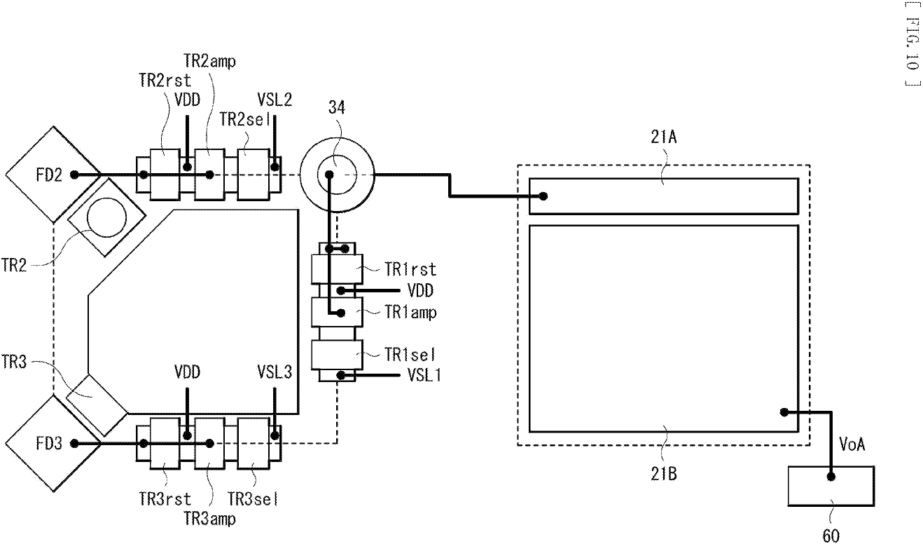

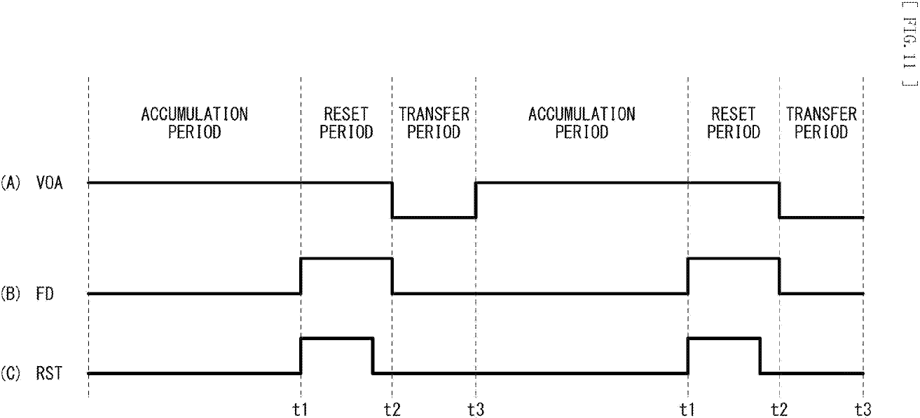

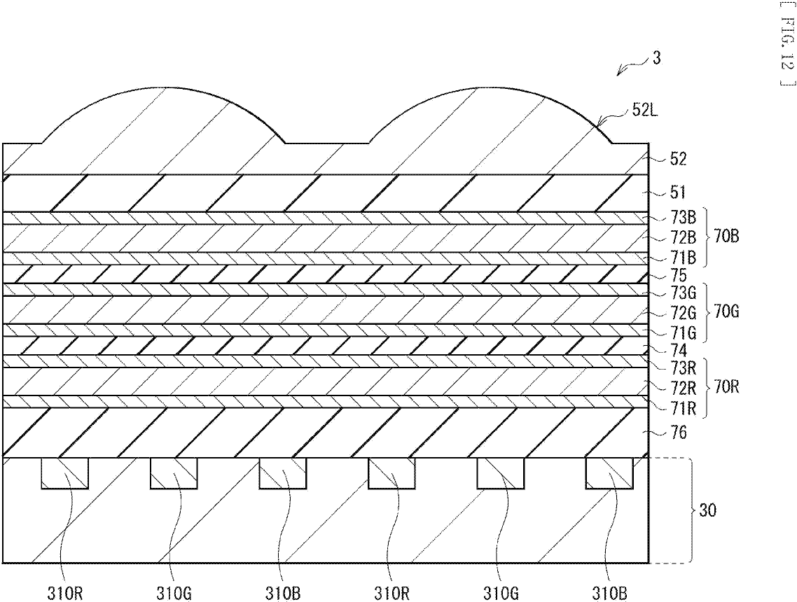

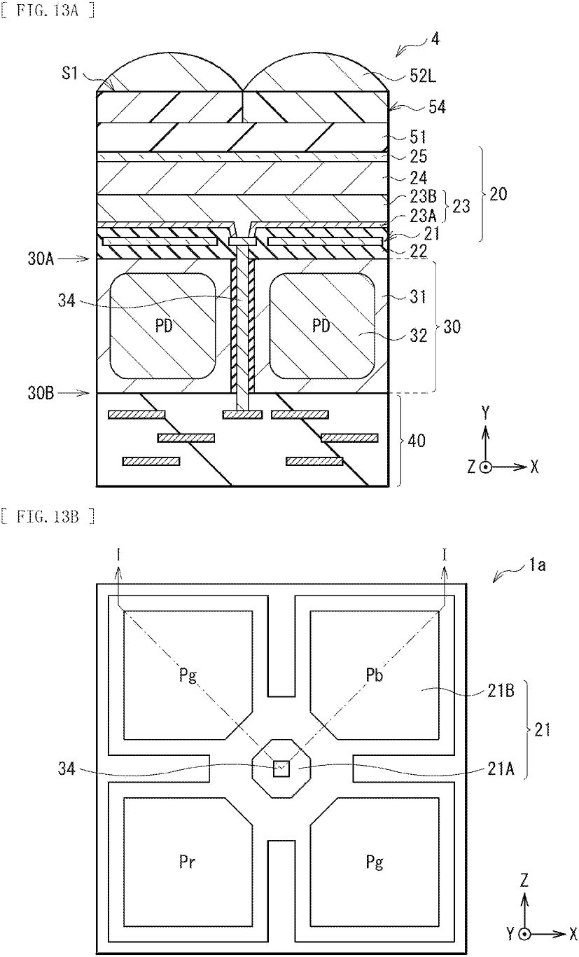

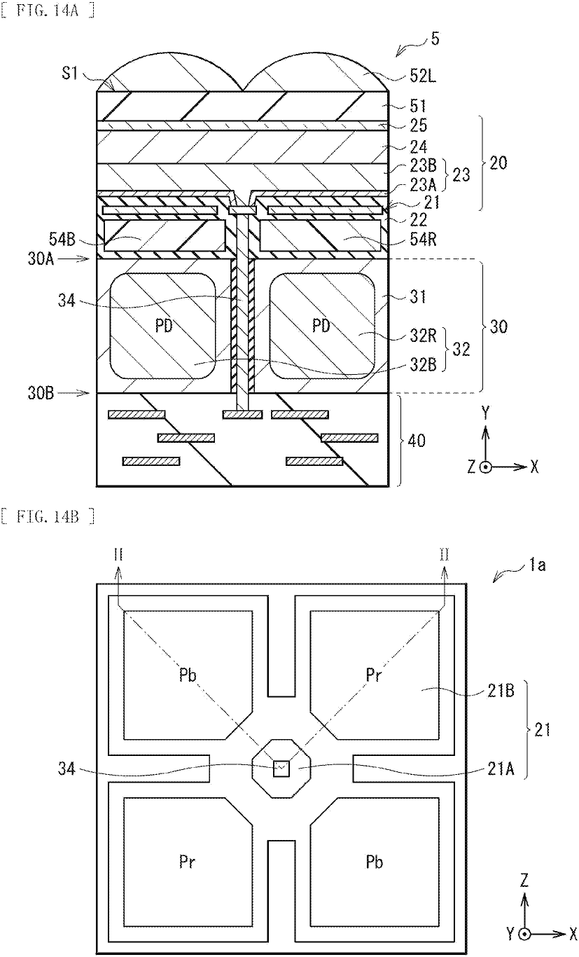

FIG. 3 is a model diagram of a crystal of the BDT3 as viewed in a direction of [301]. A stacking cycle (C) in a short axis direction of the crystal of the BDT3 molecules stacked in a herringbone structure is about 0.75 nm. In a case where crystal growth is finished at that cycle (smallest unit of the crystal), the crystal size (L1) in the short axis direction is about 1.2 nm. This value is not considered to differ significantly regardless of whether a benzene ring of the main skeleton is one or two. This crystal size in the short axis direction is defined as “larger than 1 nm” as the smallest unit of the domain. FIG. 4 is a model diagram of a crystal of the BDT3 as viewed in a direction of [20-1]. For example, in a case where two molecules are aligned in a long axis direction of molecules of the BDT3 to form a crystal, a length (L2) of the long axis (direction a) is about 6.5 nm. This direction a becomes longer as the benzene ring of the main skeleton is increased. For this reason, it is presumed that, in the organic photoelectric conversion layer 12 of the present embodiment, the one organic semiconductor material does not undergo crystal growth in the long axis direction, and molecules are stacked only in the short axis direction.

From those described above, examples of the hole-transporting material available as the one organic semiconductor material include an organic material including carbon atoms (C), hydrogen atoms (H), nitrogen atoms (N), oxygen atoms (O), and sulfur atoms (S), and including 9 or more and 13 or less aromatic rings in the entire molecules. Further, such an organic material preferably includes 5 or less aromatic rings forming the largest condensed ring, and the number of single bonds linking the aromatic rings is preferably 5 or more and 9 or less. Further, a length of the short side of the entire molecules is preferably 15% or more and 30% or less of the long side. Examples of an organic material satisfying these include compounds represented by the following formulae (2) to (7).

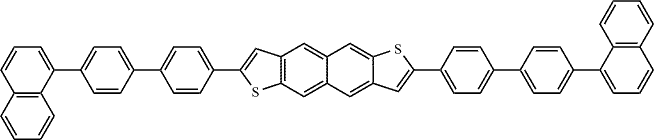 [SMILES: c1ccc2c(-c3ccc(-c4ccc(-c5cc6cc7cc8sc(-c9ccc(-c%10ccc(-c%11cccc%12ccccc%11%12)cc%10)cc9)cc8cc7cc6s5)cc4)cc3)cccc2c1]

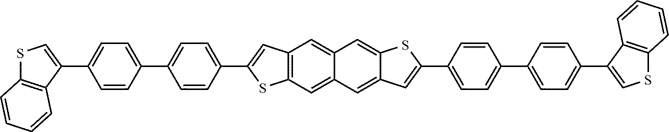 [SMILES: c1ccc2c(-c3ccc(-c4ccc(-c5cc6cc7cc8sc(-c9ccc(-c%10ccc(-c%11csc%12ccccc%11%12)cc%10)cc9)cc8cc7cc6s5)cc4)cc3)csc2c1]

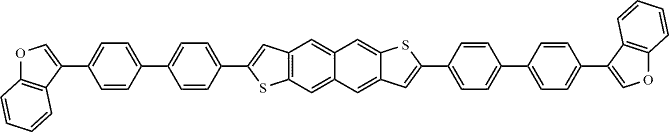 [SMILES: c1ccc2c(-c3ccc(-c4ccc(-c5cc6cc7cc8sc(-c9ccc(-c%10ccc(-c%11coc%12ccccc%11%12)cc%10)cc9)cc8cc7cc6s5)cc4)cc3)coc2c1]

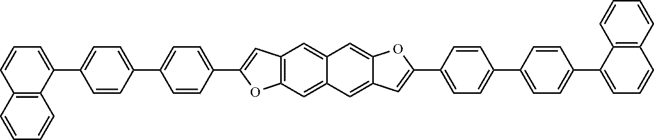 [SMILES: c1ccc2c(-c3ccc(-c4ccc(-c5cc6cc7cc8oc(-c9ccc(-c%10ccc(-c%11cccc%12ccccc%11%12)cc%10)cc9)cc8cc7cc6o5)cc4)cc3)cccc2c1]

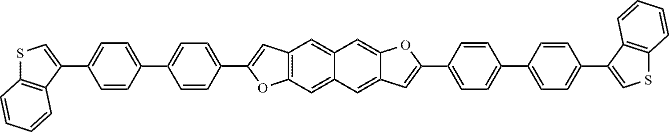 [SMILES: c1ccc2c(-c3ccc(-c4ccc(-c5cc6cc7cc8oc(-c9ccc(-c%10ccc(-c%11csc%12ccccc%11%12)cc%10)cc9)cc8cc7cc6o5)cc4)cc3)csc2c1]

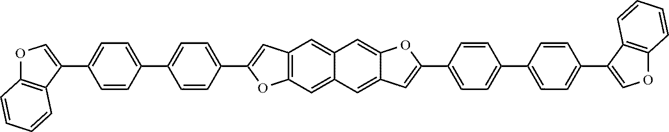 [SMILES: c1ccc2c(-c3ccc(-c4ccc(-c5cc6cc7cc8oc(-c9ccc(-c%10ccc(-c%11coc%12ccccc%11%12)cc%10)cc9)cc8cc7cc6o5)cc4)cc3)coc2c1]

The layer of the organic photoelectric conversion layer 12 has a configuration in which domains (crystal domains) each including a crystal of the above-described hole-transporting material are dispersed in the amorphous domain including C₆₀ fullerene, for example.

It is to be noted that the domains in the organic photoelectric conversion layer 12 are confirmable using a transmission electron microscope (TEM). The TEM is an apparatus that projects a three-dimensional object into two-dimensional image to capture a so-called TEM image, thus making it possible to grasp a crystal form in nm-meter order.

The crystal generally refer to a three-dimensional structure in which atoms or molecules are regularly arranged. Electrons scatter during transmission through the crystal, and interfere by wave nature of the electrons. As a result, the electrons strengthen or weaken in a specific direction. In a case where a direction of transmitted electrons relative to a cyclic structure called a crystal plane is substantially parallel, an interference fringe is observed in the TEM image. The interference fringe is generally called a lattice fringe, and a TEM image thereof is referred to here as a lattice image.

A condition in which the lattice image is observed depends on the apparatus, and an amount of focus shift (defocus amount) is observed in the vicinity of so-called Scherzer focus, in many cases, and is calculated, for example, by the following Expression (1). In the Scherzer focus, an image of a diffracted wave is formed about ¼ wavelength shifted from a transmitted wave, and a contrast is formed that is suitable for associating the lattice image with atomic arrangement. In addition, an interval (cycle) of the lattice fringe corresponds to a cycle of the crystal plane. When the focus is further shifted, the black and white of the lattice image is reversed, and moreover, the phase of the image changes variously in such a manner that a peripheral contour of the crystal becomes remarkable. In addition, the phase differs depending on an accelerating voltage of the TEM (wavelength of electrons), an aberration of a lens, the size of the crystal, and the like.

### Expression 1

$$\text{Scherzer} \text{focus} = 1.2 √ \left(\text{Cs} ⋅ λ\right)$$

(Cs: spherical aberration coefficient, λ: wavelength of electrons)

Even in a case where the crystal plane is not parallel to an electron transmission direction, shifting a focus allows for formation of a fringe (so-called fringe contrasts) in the vicinity of the contour of a scattering body (e.g., crystal) having a different density in the sample. In general, the interference fringe in the order of atomic rows or molecular rows is likely to be observed in the Scherzer focus; when the defocus amount is in the µm order, the fringe contrast tends to be relatively strong.

For the purpose of observing the scattering body difficult to be contrasted by positively utilizing this phenomenon, the defocus amount may be shifted to the µm order in some cases. This may be referred to as a defocus image in some cases; however, the Scherzer focus is also strictly the defocus image (having different order of the defocus amount).

The sample to be analyzed by the TEM generally has a thickness of about several tens of nm in the electron transmission direction. One reason for this is that electrons and materials interact strongly with each other, and thus electrons are not able to be transmitted through a sample unless the sample is thin. However, there are also examples in which the thickness is several nm for a nano carbon and in which the thickness is several hundred nm to µm in the case of observation using an ultra-high voltage electron microscope. In general, determination is made that the defocus amount is zero in a case where the contrast is the weakest, and defocusing is performed by the Scherzer focus to capture the lattice image. However, the defocus amount differs depending on the position of the sample in the electron transmission direction, and thus only a portion of the sample satisfies the Scherzer focus condition.

Meanwhile, in a case where the defocus amount is in the µm order, the defocus amount is much larger than the thickness of the sample. As a result, the contour of the scattering body such as the crystal is observed as a substantially similar fringe contrast regardless of a difference in the position in the electron transmission direction.

In the present embodiment, from those described above, in a case where a cyclic stripe pattern is observed partially in a domain in an image (TEM image) in which the domain is captured in a defocusing condition in which the focus of the TEM is shifted by 1 µm or more, the domain is defined as a crystal. Here, one reason for using the phrase “partially in a domain” results from a theoretical reason that the stripe pattern is observed only partially in the crystal due to the crystal plane being not necessarily parallel to the electron transmission direction.

Further, as for the distribution of the domains in the organic photoelectric conversion layer 12, distribution within an amorphous region is confirmable by using amorphous staining by means of osmium tetraoxide (OsO₄) and by using high-angle annular dark-field scanning transmission electron microscope (High-angle annular dark-field scanning transmission electron microscopy; HAADF-STEM).

For example, when staining is performed using a vacuum electron staining apparatus manufactured by Filgen, Inc., the amorphous region is stained, whereas a crystal portion forming the domain is not stained because a molecular spacing thereof is narrower than osmium tetraoxide. When confirming results of observations of the same field of view of the TEM image and a HAADF-STEM image, it is appreciated that a region reflected in black contrast in the HAADF-STEM image indicates the crystal domain, whereas a region reflected in white contrast indicates a stained amorphous domain.

The upper electrode 13 is configured by an electrically-conductive film having light transmissivity similar to that of the lower electrode 11. In the imaging device 100 using the photoelectric conversion element 1 as one pixel (unit pixel P), the upper electrode 13 may be separated for each of the pixels, or may be formed as an electrode common to the pixels.

It is to be noted that another layer may be provided between the organic photoelectric conversion layer 12 and the lower electrode 11, and between the organic photoelectric conversion layer 12 and the upper electrode 13. FIG. 5 illustrates another example of the cross-sectional configuration of the photoelectric conversion element 1 according to the present embodiment. Buffer layers 17A and 17B may be provided either between the organic photoelectric conversion layer 12 and the lower electrode 11 or between the organic photoelectric conversion layer 12 and the upper electrode 13; or alternatively, the buffer layers 17A and 17B may be provided both therebetween. In addition thereto, for example, an underlying layer, a hole transport layer, an electron blocking layer, and the like may be provided in this order from the side of the lower electrode 11. A hole blocking layer, a work function adjusting layer, an electron transport layer, and the like may be provided between the organic photoelectric conversion layer 12 and the upper electrode 13.

The fixed charge layer 14A may be a film having a positive fixed charge or a film having a negative fixed charge. Examples of a material of the film having a negative fixed charge include hafnium oxide (HfO₂), aluminum oxide (AI₂O₃), zirconium oxide (ZrO₂), tantalum oxide (Ta₂O₅), and titanium oxide (TiO₂). In addition, as a material other than those mentioned above, there may be used lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, an aluminum oxynitride film, or the like.

The fixed charge layer 14A may have a configuration in which two or more types of films are stacked. This makes it possible to further enhance a function as the hole accumulation layer, for example, in a case of the film having a negative fixed charge.

A material of the dielectric layer 14B is not particularly limited, and the dielectric layer 14B is formed by, for example, silicon oxide (SiOₓ), TEOS, silicon nitride (SiNₓ), silicon oxynitride (SiOₓN_{y}), or the like.

For example, the interlayer insulating layer 15 is configured by a monolayer film of one of silicon oxide (SiOₓ), silicon nitride (SiNₓ), silicon oxynitride (SiOₓN_{y}), or the like, or alternatively is configured by a stacked film of two or more thereof.

A pad section 16A, an upper contact 16B, a pad section 16C, a lower first contact 45, and a lower second contact 46 are each configured by a doped silicon material such as PDAS (Phosphorus Doped Amorphous Silicon), or a metal material such as aluminum (Al), tungsten (W), titanium (Ti), cobalt (Co), hafnium (Hf), or tantalum (Ta), for example.

The protective layer 51 is configured by a material having light transmissivity, and, for example, is configured by a monolayer film of one of silicon oxide (SiOₓ), silicon nitride (SiNₓ), silicon oxynitride (SiOₓN_{y}), or the like, or alternatively is configured by a stacked film of two or more thereof.

The on-chip lens layer 52 is formed on the protective layer 51 to cover the entire surface thereof. Multiple on-chip lenses (microlenses) 52L are provided on a front surface of the on-chip lens layer 52. The on-chip lens 52L condenses light incident from above on respective light-receiving surfaces of the organic photoelectric conversion section 10 and the inorganic photoelectric conversion sections 32B and 32R. In the present embodiment, the multilayer wiring layer 40 is formed on the side of the second surface 30S2 of the semiconductor substrate 30. This enables the respective light-receiving surfaces of the organic photoelectric conversion section 10 and the inorganic photoelectric conversion sections 32B and 32R to be arranged close to each other, thus making it possible to reduce variations in sensitivities between colors generated depending on a F-value of the on-chip lens 52L.

FIG. 2 is a plan view of a configuration example of the photoelectric conversion element 1 in which multiple photoelectric conversion sections (e.g., organic photoelectric conversion section 10 and inorganic photoelectric conversion sections 32B and 32R) are stacked to which the technology according to the present disclosure is applicable. That is, FIG. 2 illustrates an example of a planar configuration of the unit pixel P constituting the pixel section 100A of the imaging device 100 illustrated in FIG. 15, for example.

The unit pixel P includes a photoelectric conversion region 1100 in which a red photoelectric conversion section (inorganic photoelectric conversion section 32R in FIG. 1), a blue photoelectric conversion section (inorganic photoelectric conversion section 32B in FIG. 1), and a green photoelectric conversion section (organic photoelectric conversion section 10 in FIG. 1) (neither of which is illustrated in FIG. 2) that perform photoelectric conversion of light beams of respective wavelengths of R (Red), G (Green), and B (Blue) are stacked in three layers in the order of the green photoelectric conversion section, the blue photoelectric conversion section, and the red photoelectric conversion section, for example, from a side of the light-receiving surface (light incident side S1 in FIG. 1). Further, the unit pixel P includes a Tr group 1110, a Tr group 1120, and a Tr group 1130 as charge readout sections that read charges corresponding to light beams of the respective wavelengths of R, G, and B from the red photoelectric conversion section, the green photoelectric conversion section, and the blue photoelectric conversion section. The organic photoelectric conversion section 10 performs, in one unit pixel P, spectroscopy in the vertical direction, i.e., spectroscopy of light beams of R, G, and B in respective layers as the red photoelectric conversion section, the green photoelectric conversion section, and the blue photoelectric conversion section stacked in the photoelectric conversion region 1100.

The Tr group 1110, the Tr group 1120, and the Tr group 1130 are formed on the periphery of the photoelectric conversion region 1100. The Tr group 1110 outputs, as a pixel signal, a signal charge corresponding to light of R generated and accumulated in the red photoelectric conversion section. The Tr group 1110 is configured by a transfer Tr (MOS FET) 1111, a reset Tr 1112, an amplification Tr 1113, and a selection Tr 1114. The Tr group 1120 outputs, as a pixel signal, a signal charge corresponding to light of B generated and accumulated in the blue photoelectric conversion section. The Tr group 1120 is configured by a transfer Tr 1121, a reset Tr 1122, an amplification Tr 1123, and a selection Tr 1124. The Tr group 1130 outputs, as a pixel signal, a signal charge corresponding to light of G generated and accumulated in the green photoelectric conversion section. The Tr group 1130 includes a transfer Tr 1131, a reset Tr 1132, an amplification Tr 1133, and a selection Tr 1134.

The transfer Tr 1111 is configured by a gate G, a source/drain region S/D, and an FD (floating diffusion) 1115 (constituting source/drain region). The transfer Tr 1121 is configured by a gate G, a source/drain region S/D, and an FD 1125. The transfer Tr 1131 is configured by a gate G, (a source/drain region S/D coupled to) the green photoelectric conversion section of the photoelectric conversion region 1100, and an FD 1135. It is to be noted that the source/drain region of the transfer Tr 1111 is coupled to the red photoelectric conversion section of the photoelectric conversion region 1100, and that the source/drain region S/D of the transfer Tr 1121 is coupled to the blue photoelectric conversion section of the photoelectric conversion region 1100.

Each of the reset Trs 1112, 1122, and 1132, the amplification Trs 1113, 1123, and 1133, and the selection Trs 1114, 1124, and 1134 is configured by a gate G and a pair of source/drain regions S/D arranged to interpose the gate G therebetween.

The FDs 1115, 1125, and 1135 are coupled to the source/drain regions S/D serving as sources of the reset Trs 1112, 1122, and 1132, respectively, and are coupled to the gates G of the amplification Trs 1113, 1123, and 1133, respectively. A power supply Vdd is coupled to the common source/drain regions S/D in each of the reset Tr 1112 and the amplification Tr 1113, the reset Tr 1132 and the amplification Tr 1133, and the reset Tr 1122 and the amplification Tr 1123. A VSL (vertical signal line) is coupled to each of the source/drain regions S/D serving as the sources of the selection Trs 1114, 1124, and 1134.

### 1-2. Method of Manufacturing Photoelectric Conversion Element

The photoelectric conversion element 1 illustrated in FIG. 1 may be manufactured, for example, as follows.

FIGS. 6 and 7 illustrate the method of manufacturing the photoelectric conversion element 1 in the order of steps. First, as illustrated in FIG. 6, the p-well 31, for example, is formed as a well of a first electrically-conductivity type in the semiconductor substrate 30, and the inorganic photoelectric conversion sections 32B and 32R of a second electrically-conductivity type (e.g., n-type) is formed in the p-well 31. The p+ region is formed in the vicinity of the first surface 30S1 of the semiconductor substrate 30.

As illustrated in FIG. 6 as well, on the second surface 30S2 of the semiconductor substrate 30, n + regions serving as the floating diffusions FD1 to FD3 are formed, and then, a gate insulating layer 33 and a gate wiring layer 47 including respective gates of the vertical transistor Tr2, the transfer transistor Tr3, the amplifier transistor AMP, and the reset transistor RST are formed. This allows for formation of the vertical transistor Tr2, the transfer transistor Tr3, the amplifier transistor AMP, and the reset transistor RST. Further, the multilayer wiring layer 40 that includes the lower first contact 45, the lower second contact 46, the wiring layers 41 to 43 including the coupling section 41A, and the insulating layer 44 is formed on the second surface 30S2 of the semiconductor substrate 30.

As a base of the semiconductor substrate 30, for example, an SOI (Silicon on Insulator) substrate is used, in which the semiconductor substrate 30, an embedded oxide film (unillustrated), and a holding substrate (unillustrated) are stacked. Although not illustrated in FIG. 6, the embedded oxide film and the holding substrate are joined to the first surface 30S1 of the semiconductor substrate 30.

Next, a supporting substrate (unillustrated) or another semiconductor substrate, etc. is joined to the side of the second surface 30S2 (side of the multilayer wiring layer 40) of the semiconductor substrate 30, and the substrate is turned upside down. Subsequently, the semiconductor substrate 30 is separated from the embedded oxide film and the holding substrate of the SOI substrate to expose the first surface 30S1 of the semiconductor substrate 30. The above steps may be performed by techniques used in common CMOS processes such as ion implantation and CVD (Chemical Vapor Deposition).

Next, as illustrated in FIG. 7, the semiconductor substrate 30 is worked from the side of the first surface 30S1 by dry-etching, for example, to form a ring-shaped through-hole 30H. As illustrated in FIG. 7, as for the depth, the through-hole 30H penetrates from the first surface 30S1 to the second surface 30S2 of the semiconductor substrate 30, and reaches, for example, the coupling section 41A.

Subsequently, as illustrated in FIG. 7, for example, the fixed charge layer 14A is formed on the first surface 30S1 of the semiconductor substrate 30 and a side surface of the through-hole 30H. Two or more types of films may be stacked as the fixed charge layer 14A. This makes it possible to further enhance the function as the hole accumulation layer. After the fixed charge layer 14A is formed, the dielectric layer 14B is formed.

Next, an electric conductor is buried in the through-hole 30H to form the through-electrode 34. It may be possible to use, as the electric conductor, for example, a metal material such as aluminum (Al), tungsten (W), titanium (Ti), cobalt (Co), hafnium (Hf), and tantalum (Ta), in addition to a doped silicon material such as PDAS (Phosphorus Doped Amorphous Silicon).

Subsequently, after formation of the pad section 16A on the through-electrode 34, there is formed on the dielectric layer 14B and the pad section 16A, the interlayer insulating layer 15 in which the upper contact 16B and the pad section 16C that electrically couple the lower electrode 11 and the through-electrode 34 (specifically, the pad section 16A on the through-electrode 34) are provided on the pad section 16A.

Thereafter, the lower electrode 11, the organic photoelectric conversion layer 12, the upper electrode 13, and the protective layer 51 are formed in this order on the interlayer insulating layer 15. The organic photoelectric conversion layer 12 is formed, for example, by the above-described two or three types of organic materials by means of a vapor deposition method (resistive heating method), for example. At this time, allowing a substrate stage to have a predetermined temperature makes it possible to control a surface density of the domain in the organic photoelectric conversion layer 12. Finally, the on-chip lens layer 52, which includes the multiple on-chip lenses 52L, is disposed on the surface thereof. Thus, the photoelectric conversion element 1 illustrated in FIG. 1 is completed.

It is to be noted that, in a case of forming another organic layer (e.g., an electron blocking layer, etc.) on or under the organic photoelectric conversion layer 12 as described above, it is desirable to continuously form the other organic layer (by a vacuum-consistent process) in a vacuum step. In addition, the method of forming the organic photoelectric conversion layer 12 is not necessarily limited to the method using a deposition method; another method, for example, a spin-coating technique, a printing technique, or the like may be used.

In the photoelectric conversion element 1, when light is incident on the organic photoelectric conversion section 10 via the on-chip lens 52L, the light passes through the organic photoelectric conversion section 10, the inorganic photoelectric conversion sections 32B and the 32R in this order, and is subjected to photoelectric conversion for each color light beam of green (G), blue (B), and red (R) in the passing process. Hereinafter, description is given of a signal acquisition operation of each color.

### Acquisition of Green Signal by Organic Photoelectric Conversion Section 10

Green light, of the light incident on the photoelectric conversion element 1, is first selectively detected (absorbed) by the organic photoelectric conversion section 10 and is subjected to photoelectric conversion.

The organic photoelectric conversion section 10 is coupled to the gate Gamp of the amplifier transistor AMP and the floating diffusion FD1 via the through-electrode 34. Accordingly, holes of the electron-hole pairs generated in the organic photoelectric conversion section 10 are extracted from the side of the lower electrode 11, transferred to the side of the second surface 30S2 of the semiconductor substrate 30 via the through-electrode 34, and accumulated in the floating diffusion FD1. At the same time, a charge amount generated in the organic photoelectric conversion section 10 is modulated into a voltage by the amplifier transistor AMP.

In addition, the reset gate Grst of the reset transistor RST is disposed next to the floating diffusion FD1. As a result, the electric charges accumulated in the floating diffusion FD1 are reset by the reset transistor RST.

Here, the organic photoelectric conversion section 10 is coupled not only to the amplifier transistor AMP but also to the floating diffusion FD1 via the through-electrode 34, thus making it possible to easily reset the electric charges accumulated in the floating diffusion FD1 by the reset transistor RST.

On the other hand, in a case where the through-electrode 34 and the floating diffusion FD1 are not coupled to each other, it is difficult to reset the electric charges accumulated in the floating diffusion FD1, thus resulting in application of a large voltage to pull out the electric charges to the side of the upper electrode 13. Accordingly, there is a possibility that the organic photoelectric conversion layer 12 may be damaged. In addition, the structure that enables resetting in a short period of time leads to an increase in dark noises, resulting in a trade-off, which structure is thus difficult.

### Acquisition of Blue Signal and Red Signal by Inorganic Photoelectric Conversion Sections 32B and 32R

Subsequently, of the light transmitted through the organic photoelectric conversion section 10, blue light and red light are sequentially absorbed by the inorganic photoelectric conversion section 32B and the inorganic photoelectric conversion section 32R, respectively, and are subjected to photoelectric conversion. In the inorganic photoelectric conversion section 32B, electrons corresponding to the incident blue light are accumulated in an n region of the inorganic photoelectric conversion section 32B, and the accumulated electrons are transferred to the floating diffusion FD2 by the vertical transistor Tr2. Similarly, in the inorganic photoelectric conversion section 32R, electrons corresponding to the incident red light are accumulated in an n region of the inorganic photoelectric conversion section 32R, and the accumulated electrons are transferred to the floating diffusion FD3 by the transfer transistor Tr3.

### 1-3. Workings and Effects

In the photoelectric conversion element 1 of the present embodiment, the organic photoelectric conversion layer 12 having a domain larger than 1 nm and smaller than 10 nm including one organic semiconductor material is provided in a predetermined cross-section between the lower electrode 11 and the upper electrode 13. This improves movement of electric charges having undergone charge separation in the organic photoelectric conversion layer. This is described below.

The organic photoelectric conversion layer constituting the organic photoelectric conversion element to be used in an organic thin film solar cell, an organic imaging element, or the like is typically implemented by mixing different organic semiconductors together. This organic photoelectric conversion element has a mechanism in which light absorption causes electric charge pairs (excitons) including positive electric charges (holes) and negative electric charges (electrons) to be generated, and the excitons reach (diffuse to) a semiconductor interface and then move (are transported), as free electric charges, to the electrode after charge separation, thus allowing a current to flow.

An organic semiconductor typically has a dielectric constant lower than an inorganic semiconductor. As a result, the electrostatic attractive force of excitons is strong, thus making electric charges unlikely to be separated. In addition, the movement distance of excitons generated by light absorption is as short as nm order, and thus the probability is high that excitons undergo recombination (deactivation) before the excitons move to the interface and undergo charge separation. In contrast, as described above, a photoelectric conversion element with improved external quantum efficiency and response speed is reported, which is achieved by providing an organic photoelectric conversion layer having, in the layer, a percolation structure that traverses vertically in a film thickness direction and having a domain of which a domain length in a planar direction is smaller than a domain length in the film thickness direction.

Incidentally, in a case of using an organic photoelectric conversion element as an imaging element constituting an image sensor, an afterimage for a long period of time (signal delay) becomes an issue after having shot an object that emits light at low illuminance. An organic semiconductor varies greatly in its form depending on a composition thereof, a film formation condition, thermal processing after the film formation, and the like. For example, from the viewpoint of electric charge mobility, the organic semiconductor having a crystal form is more advantageous than having an amorphous form. In addition, the anisotropy of the crystal form also changes photoelectric conversion characteristics. Meanwhile, crystal fault, a grain boundary, or the like cause electric charge trapping, and the trapped electric charges are discharged over a period of time of about 10 ms to 1 s. It is considered that this deteriorates response characteristics.

As a method for solving this issue, it is conceivable to increase a drive voltage. In this case, however, an electrode to be consumed is increased, and characteristics are deteriorated due to dielectric breakdown, temperature rise, or the like, giving rise to issues such as safety and reliability to be impaired as well as manufacturing costs to be increased due to measures therefor.

In contrast, in the present embodiment, the organic photoelectric conversion layer 12 having a domain larger than 1 nm and smaller than 10 nm including one organic semiconductor material is provided in a predetermined cross-section between the lower electrode 11 and the upper electrode 13. This increases the probability that excitons generated by light absorption move to an interface between a p-type semiconductor and an n-type semiconductor and undergo charge separation.

As described above, in the photoelectric conversion element 1 of the present embodiment, excitons generated by light absorption move to the interface between the p-type semiconductor and the n-type semiconductor and undergo charge separation, and movement of free electric charges to the lower electrode 11 and the upper electrode 13 is improved. This makes it possible to improve the response characteristic including a long range of time equal to or more than 10 ms, for example. That is, in the imaging device 100 using the photoelectric conversion element 1 of the present embodiment as well as in a thermography, a ranging sensor, or the like, for example, including the imaging device 100, an afterimage for a long period of time is improved, thus enabling favorable use thereof at night.

In addition, the photoelectric conversion element 1 of the present embodiment has no need to increase the drive voltage as described above, and thus is superior also in aspects of safety, reliability, power consumption, and manufacturing costs.

Next, description is given of Modification Examples 1 to 4 of the present disclosure. It is to be noted that components corresponding to those of the photoelectric conversion element 1 of the foregoing embodiment are denoted by the same reference numerals, and descriptions thereof are omitted.

### 2. Modification Examples

### 2-1. Modification Example 1

FIG. 8 illustrates an example of a cross-sectional configuration of a photoelectric conversion element (a photoelectric conversion element 2) according to Modification Example 1 of the present disclosure. FIG. 9 is an equivalent circuit diagram of the photoelectric conversion element 2 illustrated in FIG. 8. FIG. 10 schematically illustrates arrangement of transistors constituting a control section of the photoelectric conversion element 2 and a lower electrode 21 constituting an organic photoelectric conversion section 20. The photoelectric conversion element 2 of the present modification example differs from the foregoing embodiment in that the lower electrode 21 constituting the organic photoelectric conversion section 20 includes multiple electrodes (e.g., a readout electrode 21A and an accumulation electrode 21B) independent of each other, with an insulating layer 22 interposed therebetween.

It is to be noted that description is given, in the present modification example, of a case of reading electrons, among the electron-hole pairs generated by photoelectric conversion, as signal charges (a case of setting an n-type semiconductor region as the photoelectric conversion layer).

Similarly to the foregoing first embodiment, the organic photoelectric conversion section 20 and the inorganic photoelectric conversion sections 32B and 32R selectively detect wavelengths (light) of wavelength bands different from each other and perform photoelectric conversion.

In the organic photoelectric conversion section 20, the lower electrode 21, a semiconductor layer 23, an organic photoelectric conversion layer 24, and an upper electrode 25 are stacked in this order from the side of the first surface 30S1 of the semiconductor substrate 30. In addition, the insulating layer 22 is provided between the lower electrode 21 and the semiconductor layer 23.

The lower electrode 21 is formed separately for each photoelectric conversion element 2, for example, and is configured by the readout electrode 21A and the accumulation electrode 21B separated from each other with the insulating layer 22 interposed therebetween, as described above. The readout electrode 21A is electrically coupled to the semiconductor layer 23 via an opening 22H provided in the insulating layer 22. The readout electrode 21A is provided to transfer electric charge generated in the organic photoelectric conversion layer 24 to the floating diffusion FD1, and is coupled to the floating diffusion FD 1 via an upper second contact 29B, a pad section 39A, an upper first contact 29A, the through-electrode 34, the coupling section 41A, and the lower second contact 46, for example. The accumulation electrode 21B is provided to accumulate, in the semiconductor layer 23, electrons, among electric charges generated in the organic photoelectric conversion layer 24, as signal charges. The accumulation electrode 21B is provided in a region opposed to and covering the light receiving surface of the inorganic photoelectric conversion sections 32B and 32R formed in the semiconductor substrate 30. The accumulation electrode 21B is preferably larger than the readout electrode 21A, which makes it possible to accumulate a number of electric charges. As illustrated in FIG. 10, a voltage application circuit 60 is coupled to the accumulation electrode 21B via a wiring line, and a voltage (e.g., Vo_{A}) is independently applied thereto.

The insulating layer 22 is provided to electrically separate the accumulation electrode 21B and the semiconductor layer 23 from each other. The insulating layer 22 is provided on an interlayer insulating layer 28, for example, to cover the lower electrode 21. The insulating layer 22 is provided with the opening 22H on the readout electrode 21A, and the readout electrode 21A and the semiconductor layer 23 are electrically coupled to each other via the opening 22H. For example, the insulating layer 22 is configured by a monolayer film of one of silicon oxide (SiOₓ), silicon nitride (SiNₓ), silicon oxynitride (SiOₓN_{y}), or the like, or alternatively is configured by a stacked film of two or more thereof.

The semiconductor layer 23 is provided under the organic photoelectric conversion layer 24, specifically, between the insulating layer 22 and the organic photoelectric conversion layer 24, and is provided to accumulate signal charges generated in the organic photoelectric conversion layer 24. It is preferable for the semiconductor layer 23 to have electric charge mobility higher than and to be formed by using a material having a band gap larger than those of the organic photoelectric conversion layer 24. For example, the band gap of a constituent material of the semiconductor layer 23 is preferably 3.0 eV or more. Examples of such a material include an oxide semiconductor material such as IGZO and an organic semiconductor material. Examples of the organic semiconductor material include transition metal dichalcogenide, silicon carbide, diamond, graphene, a carbon nanotube, a condensed polycyclic hydrocarbon compound, and a condensed heterocyclic compound. Providing the semiconductor layer 23 configured by the above-mentioned material under the organic photoelectric conversion layer 24 makes it possible to prevent recombination of electric charges at the time of accumulation of electric charges and thus to improve transmission efficiency.

It is to be noted that, as in photoelectric conversion elements 4 and 5 described later, for example, the semiconductor layer 23 may have, for example, a stacked structure of a layer (a layer 23A) and a layer (a layer 23B). The layer 23A is provided to prevent electric charges accumulated in the semiconductor layer 23 from being trapped at an interface with the insulating layer 22 and transfer the electric charges efficiently to a readout electrode 11A. The layer 23B is provided to prevent oxygen desorption on a front surface of the layer 23A and prevent electric charges generated in the organic photoelectric conversion layer 24 from being trapped at an interface with the semiconductor layer 23.

The organic photoelectric conversion layer 24 converts optical energy into electric energy, and has a configuration similar to that of the organic photoelectric conversion layer 12 in the foregoing embodiment.

Similarly to the upper electrode 13 in the foregoing embodiment, the upper electrode 25 is configured by an electrically-conductive film having light transmissivity.

It is to be noted that, although FIG. 8 illustrates the example in which the semiconductor layer 23, the organic photoelectric conversion layer 24, and the upper electrode 25 are provided as successive layers common to multiple photoelectric conversion elements 2, these layers may be formed separately for each of the photoelectric conversion elements 2, for example. In addition, another layer may be provided between the semiconductor layer 23 and the organic photoelectric conversion layer 24, and between the organic photoelectric conversion layer 24 and the upper electrode 25. For example, similarly to the photoelectric conversion element 1 illustrated in FIG. 5, the buffer layers 17A and 17B may be provided between the organic photoelectric conversion layer 24 and the lower electrode 21 and between the organic photoelectric conversion layer 24 and the upper electrode 25, for example.

For example, a dielectric layer 26, an insulating layer 27, and the interlayer insulating layer 28 are provided between the first surface 30S1 of the semiconductor substrate 30 and the lower electrode 21. The dielectric layer 26, the insulating layer 27, and the interlayer insulating layer 28 have configurations similar to those of the fixed charge layer 14A, the dielectric layer 14B, and the interlayer insulating layer 15, respectively, in the foregoing embodiment.

A second surface 30B of the semiconductor substrate 30 is provided with a readout circuit constituting a control section in each of the organic photoelectric conversion section 20 and the inorganic photoelectric conversion sections 32B and 32R. Specifically, there are provided: a reset transistor TR1rst, an amplifier transistor TR1amp, and a selection transistor TR1sel constituting a readout circuit of the organic photoelectric conversion section 20; a transfer transistor TR2trs (TR2), a reset transistor TR2rst, an amplifier transistor TR2amp, and a selection transistor TR2sel constituting a readout circuit of the inorganic photoelectric conversion section 32B; and a transfer transistor TR3trs (TR3), a reset transistor TR3rst, an amplifier transistor TR3amp, and a selection transistor TR3sel constituting a readout circuit of the inorganic photoelectric conversion section 32R.

The reset transistor TR1rst resets electric charges transferred from the organic photoelectric conversion section 20 to the floating diffusion FD1, and is configured by, for example, a MOS transistor. Specifically, the reset transistor Tr1rst is configured by the reset gate Grst, a channel formation region 36A, and source/drain regions 36B and 36C. The reset gate Grst is coupled to a reset line RST1, and one source/drain region 36B of the reset transistor Tr1rst also serves as the floating diffusion FD1. Another source/drain region 36C constituting the reset transistor Tr1rst is coupled to a power source VDD.

The amplifier transistor TR1amp is a modulation element that modulates an amount of electric charges generated in the organic photoelectric conversion section 20 into a voltage, and is configured by, for example, a MOS transistor. Specifically, the amplifier transistor TR1amp is configured by the gate Gamp, a channel formation region 35A, and source/drain regions 35B and 35C. The gate Gamp is coupled to the readout electrode 21A and the one source/drain region 36B (floating diffusion FD1) of the reset transistor Tr1rst via the lower first contact 45, the coupling section 41A, the lower second contact 46, the through-electrode 34, and the like. In addition, one source/drain region 35B shares a region with the other source/drain region 36C constituting the reset transistor Tr1rst, and is coupled to the power source VDD.

The selection transistor TR1se1 is configured by a gate Gse1, a channel formation region 34A, and source/drain regions 34B and 34C. The gate Gse1 is coupled to a selection line SEL1. In addition, one source/drain region 34B shares a region with another source/drain region 35C constituting the amplifier transistor AMP, and another source/drain region 34C is coupled to the signal line (data output line) VSL1.

The transfer transistor TR2trs (TR2) is provided to transfer, to the floating diffusion FD2, signal charges corresponding to a blue color generated and accumulated in an inorganic photoelectric conversion section 32G. The inorganic photoelectric conversion section 32G is formed at a deep position from the second surface 30S2 of the semiconductor substrate 30, and thus the transfer transistor TR2trs of the inorganic photoelectric conversion section 32G is preferably configured by a vertical transistor. In addition, the transfer transistor TR2trs is coupled to a transfer gate line TG2. Further, the floating diffusion FD2 is provided in a region 37C in the vicinity of the gate Gtrs2 of the transfer transistor TR2trs. The electric charges accumulated in the inorganic photoelectric conversion section 32G is read by the floating diffusion FD2 via a transfer channel formed along the gate Gtrs2.

The reset transistor TR2rst is configured by a gate, a channel formation region, and source/drain regions. A gate of the reset transistor TR2rst is coupled to a reset line RST2, and one of the source/drain regions of the reset transistor TR2rst is coupled to the power source VDD. Another of the source/drain regions of the reset transistor TR2rst also serves as the floating diffusion FD2.

The amplifier transistor TR2amp is configured by a gate, a channel formation region, and source/drain regions. The gate is coupled to the other source/drain region (floating diffusion FD2) of the reset transistor TR2rst. In addition, one of the source/drain regions constituting the amplifier transistor TR2amp shares a region with the one of the source/drain regions constituting the reset transistor TR2rst, and is coupled to the power source VDD.

The selection transistor TR2sel is configured by a gate, a channel formation region, and source/drain regions. The gate is coupled to a selection line SEL2. In addition, one of the source/drain regions constituting the selection transistor TR2sel shares a region with another of the source/drain regions constituting the amplifier transistor TR2amp. Another of the source/drain regions constituting the selection transistor TR2sel is coupled to a signal line (data output line) VSL2.

The transfer transistor TR3trs (TR3) transfers, to the floating diffusion FD3, signal charges corresponding to a red color generated and accumulated in the inorganic photoelectric conversion section 32R, and is configured by, for example, a MOS transistor. In addition, the transfer transistor TR3trs is coupled to a transfer gate line TG3. Further, the floating diffusion FD3 is provided in a region 38C in the vicinity of a gate Gtrs3 of the transfer transistor TR3trs. The electric charges accumulated in the inorganic photoelectric conversion section 32R is read by the floating diffusion FD3 via a transfer channel formed along the gate Gtrs3.

The reset transistor TR3rst is configured by a gate, a channel formation region, and source/drain regions. A gate of the reset transistor TR3rst is coupled to a reset line RST3, and one of the source/drain regions constituting the reset transistor TR3rst is coupled to the power source VDD. Another of the source/drain regions constituting the reset transistor TR3rst also serves as the floating diffusion FD3.

The amplifier transistor TR3amp is configured by a gate, a channel formation region, and source/drain regions. The gate is coupled to the other source/drain region (floating diffusion FD3) of the reset transistor TR3rst. In addition, one of the source/drain regions constituting the amplifier transistor TR3amp shares a region with the one of the source/drain regions constituting the reset transistor TR3rst, and is coupled to the power source VDD.

The selection transistor TR3sel is configured by a gate, a channel formation region, and source/drain regions. The gate is coupled to a selection line SEL3. In addition, one of the source/drain regions constituting the selection transistor TR3sel shares a region with another of the source/drain regions constituting the amplifier transistor TR3amp. Another of the source/drain regions constituting the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit 111 constituting a drive circuit. The signal lines (data output lines) VSL1, VSL2, and VSL3 are coupled to a column signal processing circuit 112 constituting the drive circuit.

The protective layer 51 is provided on the upper electrode 25. In the protective layer 51, for example, a light blocking film 53 is provided at a position corresponding to the readout electrode 21A. This light blocking film 53 may be provided to cover at least a region of the readout electrode 21A in direct contact with the semiconductor layer 23, without being engaged with at least the accumulation electrode 21B.

FIG. 11 illustrates an operational example of the photoelectric conversion element 2. (A) indicates a potential in the accumulation electrode 21B, (B) indicates a potential in the floating diffusion FD1 (readout electrode 21A), and (C) indicates a potential in the gate (Gse1) of the reset transistor TR1rst. In the photoelectric conversion element 2, voltages are applied individually to the readout electrode 21A and the accumulation electrode 21B.

In the photoelectric conversion element 2, during an accumulation period, a potential V1 is applied from the drive circuit to the readout electrode 21A, and a potential V2 is applied to the accumulation electrode 21B. Here, as for the potentials V1 and V2, V2 > V1 holds true. This allows electric charges (signal charges; electrons) generated by photoelectric conversion to be attracted to the accumulation electrode 21B and accumulated in a region, of the semiconductor layer 23, opposed to the accumulation electrode 21B (accumulation period). Incidentally, a potential in the region, of the semiconductor layer 23, opposed to the accumulation electrode 21B has a value on a more negative side as time of photoelectric conversion elapses. It is to be noted that holes are sent from the upper electrode 13 to the drive circuit.

In the photoelectric conversion element 2, a reset operation is performed at a later stage in the accumulation period. Specifically, at timing t1, a scanning section changes a voltage of a reset signal RST from a low level to a high level. This brings, in the unit pixel P, the reset transistor TR1rst into an ON state; as a result, a voltage of the floating diffusion FD1 is set to a power source voltage, and the voltage of the floating diffusion FD1 is reset (reset period).

After completion of the reset operation, electric charges are read. Specifically, at timing t2, a potential V3 is applied to the readout electrode 21A from the drive circuit, and a potential V4 is applied to the accumulation electrode 21B. Here, as for the potentials V3 and V4, V3 < V4 holds true. This allows electric charges accumulated in a region corresponding to the accumulation electrode 21B to be read from the readout electrode 21A to the floating diffusion FD1. That is, the electric charges accumulated in the semiconductor layer 23 are read by the control section (transfer period).

After completion of the reading operation, the potential V1 is applied again to the readout electrode 21A from the drive circuit, and the potential V2 is applied to the accumulation electrode 21B. This allows electric charges generated by photoelectric conversion to be attracted to the accumulation electrode 21B and accumulated in a region, of the organic photoelectric conversion layer 24, opposed to the accumulation electrode 21B (accumulation period).

As described above, the present technology is applicable to the photoelectric conversion element (photoelectric conversion element 2) in which the lower electrode 21 includes the multiple electrodes (readout electrode 21A and accumulation electrode 21B). That is, in the photoelectric conversion element 2 of the present modification example, the organic photoelectric conversion layer 24 is formed to have a domain larger than 1 nm and smaller than 10 nm including one organic semiconductor material in a predetermined cross-section between the lower electrode 21 and the upper electrode 25, thereby making it easier for electric charges (electrons and holes) generated in the organic photoelectric conversion layer 24 to move to the lower electrode 21 and the upper electrode 25. Thus, it is possible to obtain effects similar to those of the foregoing embodiment.

### 2-2. Modification Example 2

FIG. 12 schematically illustrates an example of a cross-sectional configuration of a photoelectric conversion element (a photoelectric conversion element 3) according to Modification Example 2 of the present disclosure. Similarly to the above-described photoelectric conversion element 1, for example, the photoelectric conversion element 3 constitutes one unit pixel P in the imaging device 100 such as a CMOS image sensor that is able to capture an image obtained from visible light, for example, without using a color filter. The photoelectric conversion element 3 of the present modification example has a configuration in which a red photoelectric conversion section 70R, a green photoelectric conversion section 70G, and a blue photoelectric conversion section 70B are stacked in this order on the semiconductor substrate 30, with an insulating layer 76 interposed therebetween.

The red photoelectric conversion section 70R, the green photoelectric conversion section 70G, and the blue photoelectric conversion section 70B include, respectively, organic photoelectric conversion layers 72R, 72G, and 72B between respective pairs of electrodes, specifically, between a lower electrode 71R and an upper electrode 73R, between a lower electrode 71G and an upper electrode 73G, and between a lower electrode 71B and an upper electrode 73B, respectively.

The on-chip lens layer 52 including the on-chip lens 52L is provided over the blue photoelectric conversion section 70B with the protective layer 51 interposed therebetween. A red electricity storage layer 310R, a green electricity storage layer 310G, and a blue electricity storage layer 310B are provided in the semiconductor substrate 30. Light incident on the on-chip lens 52L is photoelectrically converted, by the red photoelectric conversion section 70R, the green photoelectric conversion section 70G, and the blue photoelectric conversion section 70B, and respective signal charges are sent, from the red photoelectric conversion section 70R to the red electricity storage layer 310R, from the green photoelectric conversion section 70G to the green electricity storage layer 310G, and from the blue photoelectric conversion section 70B to the blue electricity storage layer 310B. The signal charges may be either electrons or holes generated by photoelectric conversion; however, in the following, description is given by exemplifying a case where electrons are read as the signal charges.

The semiconductor substrate 30 is configured by, for example, a p-type silicon substrate. The red electricity storage layer 310R, the green electricity storage layer 310G, and the blue electricity storage layer 310B provided in the semiconductor substrate 30 each include the n-type semiconductor region, and the signal charges (electrons) supplied from the red photoelectric conversion section 70R, the green photoelectric conversion section 70G, and the blue photoelectric conversion section 70B are accumulated in the n-type semiconductor region. The n-type semiconductor region of the red electricity storage layer 310R, the green electricity storage layer 310G, and the blue electricity storage layer 310B is formed, for example, by doping the semiconductor substrate 30 with n-type impurities such as phosphorus (P) or arsenic (As). It is to be noted that the semiconductor substrate 30 may be provided on a support substrate (unillustrated) including glass or the like.

The semiconductor substrate 30 is provided with a pixel transistor for reading electrons from each of the red electricity storage layer 310R, the green electricity storage layer 310G, and the blue electricity storage layer 310B and transferring them, for example, to a vertical signal line (a vertical signal line Lsig in FIG. 15). A floating diffusion of this pixel transistor is provided in the semiconductor substrate 30, and this floating diffusion is coupled to the red electricity storage layer 310R, the green electricity storage layer 310G, and the blue electricity storage layer 310B. The floating diffusion is configured by the n-type semiconductor region.

The insulating layer 76 is configured by, for example, silicon oxide (SiOₓ), silicon nitride (SiNₓ), silicon oxynitride (SiON), hafnium oxide (HfOₓ), or the like. Multiple types of insulating films may be stacked to configure the insulating layer 76. The insulating layer 76 may be configured by an organic insulating material. The insulating layer 76 is provided with respective plugs and electrodes for coupling the red electricity storage layer 310R and the red photoelectric conversion section 70R together, the green electricity storage layer 310G and the green photoelectric conversion section 70G together, and the blue electricity storage layer 310B and the blue photoelectric conversion section 70B together.

The red photoelectric conversion section 70R includes the lower electrode 71R, the organic photoelectric conversion layer 72R, and the upper electrode 73R in this order from a position close to the semiconductor substrate 30. The green photoelectric conversion section 70G includes the lower electrode 71G, the organic photoelectric conversion layer 72G, and the upper electrode 73G in this order from a position close to the red photoelectric conversion section 70R. The blue photoelectric conversion section 70B includes the lower electrode 71B, the organic photoelectric conversion layer 72B, and the upper electrode 73B in this order from a position close to the green photoelectric conversion section 70G. The insulating layer 44 is provided between the red photoelectric conversion section 70R and the green photoelectric conversion section 70G, and an insulating layer 75 is provided between the green photoelectric conversion section 70G and the blue photoelectric conversion section 70B. The red photoelectric conversion section 70R selectively absorbs red light (e.g., a wavelength of 620 nm or more and 750 nm or less); the green photoelectric conversion section 70G selectively absorbs green light (e.g., a wavelength of 495 nm or more and 620 nm or less); and the blue photoelectric conversion section 70B selectively absorbs blue light (e.g., a wavelength of 450 nm or more and 495 nm or less) to generate electron-hole pairs.

The lower electrode 71R extracts signal charges generated in the organic photoelectric conversion layer 72R; the lower electrode 71G extracts signal charges generated in the organic photoelectric conversion layer 72G; and the lower electrode 71B extracts signal charges generated in the organic photoelectric conversion layer 72B. The lower electrodes 71R, 71G, and 71B are provided for each pixel, for example. The lower electrodes 71R, 71G, and 71B are each configured by, for example, a light-transmissive electrically-conductive material, specifically, ITO. The lower electrodes 71R, 71G, and 71B may be configured by, for example, a tin oxide-based material or a zinc oxide-based material. The tin oxide-based material is a material in which tin oxide is doped with a dopant. The zinc oxide-based material is, for example, an aluminum zinc oxide in which zinc oxide is doped with aluminum as a dopant, a gallium zinc oxide in which zinc oxide is doped with gallium as a dopant, an indium zinc oxide in which zinc oxide is doped with indium as a dopant, or the like. Alternatively, it may also be possible to use IGZO, CuI, InSbO₄, ZnMgO, CuInO₂, MgIn₂O₄, CdOs, ZnSnO₃, and the like.

For example, an electron transport layer or the like may be provided between the lower electrode 71R and the organic photoelectric conversion layer 72R, between the lower electrode 71G and the organic photoelectric conversion layer 72G, and between the lower electrode 71B and the organic photoelectric conversion layer 72B. The electron transport layer is provided to facilitate the supply of electrons generated in the organic photoelectric conversion layers 72R, 72G, and 72B to the lower electrodes 71R, 71G, and 71B, and is configured by, for example, titanium oxide, zinc oxide, or the like. Titanium oxide and zinc oxide may be stacked to configure the electron transport layer.

Each of the organic photoelectric conversion layers 72R, 72G, and 72B absorbs and photoelectrically converts light of a selective wavelength region, and transmits light of another wavelength region. Here, the light of a selective wavelength region is: for example, light of a wavelength region having a wavelength of 620 nm or more and less than 770 nm for the organic photoelectric conversion layer 72R; for example, light of a wavelength region having a wavelength of 495 nm or more and less than 620 nm for the organic photoelectric conversion layer 72G; and, for example, light of a wavelength region having a wavelength of 450 nm or more and less than 495 nm for the organic photoelectric conversion layer 72B.

The organic photoelectric conversion layers 72R, 72G, and 72B each have a configuration similar to that of the organic photoelectric conversion layer 12 in the foregoing embodiment.

For example, a hole transport layer or the like may be provided between the organic photoelectric conversion layer 72R and the upper electrode 73R, between the organic photoelectric conversion layer 72G and the upper electrode and 73G, and between the organic photoelectric conversion layer 72B and the upper electrode 73B. The hole transport layer is provided to facilitate the supply of holes generated in the organic photoelectric conversion layers 72R, 72G, and 72B to the upper electrodes 73R, 73G, and 73B, and is configured by, for example, molybdenum oxide, nickel oxide, vanadium oxide, or the like. Alternatively, an organic material such as PEDOT (Poly(3,4-ethylenedioxythiophene)) and TPD (N,N′-Bis(3-methylphenyl)-N,N′-diphenylbenzidine) may be used to form the hole transport layer.

The upper electrode 73R is provided to extract holes generated in the organic photoelectric conversion layer 72R. The upper electrode 73G is provided to extract holes generated in the organic photoelectric conversion layer 72G. The upper electrode 73B is provided to extract holes generated in the organic photoelectric conversion layer 72G. Holes extracted from the upper electrodes 73R, 73G, and 73B are discharged, via respective transmission paths (unillustrated), to a p-type semiconductor region (unillustrated) in the semiconductor substrate 30, for example. The upper electrodes 73R, 73G, and 73B are each configured by, for example, an electrically-conductive material such as gold (Au), silver (Ag), copper (Cu), and aluminum (Al). Similarly to the lower electrodes 71R, 71G, and 71B, the upper electrodes 73R, 73G, and 73B may be each configured by a transparent electrically-conductive material. In the photoelectric conversion element 3, holes extracted from the upper electrodes 73R, 73G, and 73B are discharged. Thus, for example, when multiple photoelectric conversion elements 3 are disposed in the imaging device 100 described later, the upper electrodes 73R, 73G, and 73B may be provided in common to the photoelectric conversion elements 3 (unit pixels P).

An insulating layer 74 is provided to insulate the upper electrode 73R and the lower electrode 71G from each other, and an insulating layer 75 is provided to insulate the upper electrode 73G and the lower electrode 71B from each other. The insulating layers 74 and 75 are each configured by, for example, a metal oxide, a metal sulfide, or an organic matter. Examples of the metal oxide include silicon oxide (SiOₓ), aluminum oxide (A1Oₓ), zirconium oxide (ZrOₓ), titanium oxide (TiOₓ), zinc oxide (ZnO_{X}), tungsten oxide (WOₓ), magnesium oxide (MgOₓ), niobium oxide (NbOₓ), tin oxide (SnOₓ), and gallium oxide (GaO_{X}). Examples of the metal sulfide include zinc sulfide (ZnS), and magnesium sulfide (MgS). For example, the band gap of a constituent material of each of the insulating layers 74 and 75 is preferably 3.0 eV or more.

As described above, the present technology is also applicable to the photoelectric conversion element (organic photoelectric conversion element 3) in which the red photoelectric conversion section 70R, the green photoelectric conversion section 70G, and the blue photoelectric conversion section 70B are stacked in this order, which include the respective photoelectric conversion layers (photoelectric conversion layers 72R, 72G, and 72B) configured using organic semiconductor materials. That is, in the photoelectric conversion element 3 of the present modification example, the organic photoelectric conversion layers 72R, 72G, and 72B are formed to have respective domains larger than 1 nm and smaller than 10 nm including one organic semiconductor material in respective predetermined cross-sections between the lower electrodes 71R, 71G, and 71B and the upper electrodes 73R, 73G, and 73B, thereby making it easier for electric charges (electrons and holes) generated in the organic photoelectric conversion layers 72R, 72G, and 72B to move to the lower electrodes 71R, 71G, and 71B and the upper electrodes 73R, 73G, and 73B, respectively. Thus, it is possible to obtain effects similar to those of the foregoing embodiment.

### 2-3. Modification Example 3

FIG. 13A schematically illustrates a cross-sectional configuration of a photoelectric conversion element 4 of Modification Example 3 of the present disclosure. FIG. 13B schematically illustrates an example of a planar configuration of the photoelectric conversion element 4 illustrated in FIG. 13A. FIG. 13A illustrates a cross-section along a line I-I illustrated in FIG. 13B. The photoelectric conversion element 4 is, for example, a stacked photoelectric conversion element in which an inorganic photoelectric conversion section 32 and the organic photoelectric conversion section 20 are stacked. In the pixel section 100A of the imaging device (e.g., imaging device 100) including the photoelectric conversion element 4, a pixel unit 1a including four pixels arranged in two rows × two columns is a repeating unit, for example, as illustrated in FIG. 13B, and the pixel units 1a are repeatedly arranged in array in a row direction and a column direction.

The photoelectric conversion element 4 of the present modification example is provided with color filters 54 above the organic photoelectric conversion section 20 (light incident side S1) for the respective unit pixels P. The respective color filters 54 selectively transmit red light (R), green light (G), and blue light (B). Specifically, in the pixel unit 1a including the four pixels arranged in two rows × two columns, two color filters each of which selectively transmits green light (G) are disposed on a diagonal line, and color filters that selectively transmit red light (R) and blue light (B) are arranged one by one on the orthogonal diagonal line. Unit pixels (Pr, Pg, and Pb) provided with the respective color filters each detect the corresponding color light, for example, in the organic photoelectric conversion section 20. That is, the respective pixels (Pr, Pg, and Pb) that detect red light (R), green light (G), and blue light (B) have a Bayer arrangement in the pixel section 100A.

The organic photoelectric conversion section 20 includes, for example, the lower electrode 21, the insulating layer 22, the semiconductor layer 23, the organic photoelectric conversion layer 24, and the upper electrode 25. The lower electrode 21, the insulating layer 22, the semiconductor layer 23, and the upper electrode 25 each have a configuration similar to that of the organic photoelectric conversion section 20 in the foregoing Modification Example 1. For example, similarly to the foregoing embodiment, the organic photoelectric conversion layer 24 is formed to have a domain larger than 1 nm and smaller than 10 nm including one organic semiconductor material in a predetermined cross-section between the lower electrode 21 and the upper electrode 25, and to have absorption between visible light and near infrared light. The inorganic photoelectric conversion section 32 detects light of a wavelength region (e.g., light of an infrared light region (infrared light (IR)) of 700 nm or more and 1000 nm or less) different from that of the organic photoelectric conversion section 20.

In the photoelectric conversion element 4, light beams (red light (R), green light (G), and blue light (B)) of the visible light region, among the light beams transmitted through the color filters 54, are absorbed by the organic photoelectric conversion sections 20 of the unit pixels (Pr, Pg, and Pb) provided with the respective color filters. The other light, e.g., infrared light (IR) is transmitted through the organic photoelectric conversion section 20. This infrared light (IR) transmitted through the organic photoelectric conversion section 20 is detected by the inorganic photoelectric conversion section 32 of each of the unit pixels Pr, Pg, and Pb. Each of the unit pixels Pr, Pg, and Pb generates signal charges corresponding to the infrared light (IR). That is, the imaging device 100 including the photoelectric conversion element 4 is able to simultaneously generate both a visible light image and an infrared light image.

### 2-4. Modification Example 4

FIG. 14A schematically illustrates a cross-sectional configuration of a photoelectric conversion element 5 of Modification Example 4 of the present disclosure. FIG. 14B schematically illustrates an example of a planar configuration of the photoelectric conversion element 5 illustrated in FIG. 14A. FIG. 14A illustrates a cross-section along a line II-II illustrated in FIG. 14B. In the foregoing Modification Example 3, the example has been described in which the color filters 54 that selectively transmit red light (R), green light (G), and blue light (B) are provided above the organic photoelectric conversion section 20 (light incident side S1), but the color filter 54 may be provided between the inorganic photoelectric conversion section 32 and the organic photoelectric conversion section 20, for example, as illustrated in FIG. 14A.

For example, the color filters 54 in the photoelectric conversion element 5 have a configuration in which color filters (color filters 54R) each of which selectively transmits at least red light (R) and color filters (color filters 54B) each of which selectively transmits at least blue light (B) are arranged on the respective diagonal lines in the pixel unit 1a. Similarly to Modification Example 1, for example, the organic photoelectric conversion section 20 (organic photoelectric conversion layer 24) is configured to selectively absorb a wavelength corresponding to green light. This allows the organic photoelectric conversion sections 20 and the respective inorganic photoelectric conversion sections 32 (inorganic photoelectric conversion sections 32R and 32G) arranged below the color filters 54R and 55B to acquire signals corresponding to blue light (B) or red light (R). The photoelectric conversion element 5 according to the present modification example allows the respective photoelectric conversion sections of R, G, and B to each have larger area than that of a photoelectric conversion element having a typical Bayer arrangement. This makes it possible to improve the S/N ratio.

It is to be noted that, in the foregoing Modification Examples 3 and 4, the example has been described in which the lower electrode 21 constituting the organic photoelectric conversion section 20 includes the multiple electrodes (readout electrode 21A and accumulation electrode 21B); however, as in the photoelectric conversion element 1 in the foregoing embodiment, the present modification example is also applicable to the case where the lower electrode includes one electrode for each unit pixel P, thus making it possible to obtain effects similar to those of the present modification example.

### 3. Application Examples

### Application Example 1

FIG. 15 illustrates an example of an overall configuration of the imaging device (imaging device 100) including the photoelectric conversion element (e.g., photoelectric conversion element 1) illustrated in FIG. 1, for example.

The imaging device 100 is, for example, a CMOS image sensor. The imaging device 100 takes in incident light (image light) from a subject via an optical lens system (unillustrated), and converts the amount of incident light formed on an imaging surface as an image into electric signals in units of pixels to output the electric signals as pixel signals. The imaging device 100 includes the pixel section 100A as an imaging area on the semiconductor substrate 30. In addition, the imaging device 100 includes, for example, the vertical drive circuit 111, the column signal processing circuit 112, a horizontal drive circuit 113, an output circuit 114, a control circuit 115, and an input/output terminal 116 in a peripheral region of this pixel section 100A.

The pixel section 100A includes, for example, the multiple unit pixels P that are two-dimensionally arranged in matrix. The unit pixels P are provided, for example, with a pixel drive line Lread (specifically, a row selection line and a reset control line) for each of pixel rows and provided with the vertical signal line Lsig for each of pixel columns. The pixel drive line Lread transmits drive signals for reading signals from the pixels. One end of the pixel drive line Lread is coupled to an output terminal of the vertical drive circuit 111 corresponding to each of the rows.

The vertical drive circuit 111 is a pixel drive section that is configured by a shift register, an address decoder, and the like and drives the unit pixels P of the pixel section 100A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by this horizontal drive circuit 113 causes signals of the respective pixels transmitted through the respective vertical signal lines Lsig to be outputted to a horizontal signal line 121 in order and causes the signals to be transmitted to the outside of the semiconductor substrate 30 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 30, or may be provided on an external control IC. In addition, the circuit portion may be formed in another substrate coupled by a cable or the like.

The control circuit 115 receives a clock supplied from the outside of the semiconductor substrate 30, data for an instruction about an operation mode, and the like and also outputs data such as internal information on the imaging device 100. The control circuit 115 further includes a timing generator that generates a variety of timing signals, and controls driving of the peripheral circuits including the vertical drive circuit 111, the column signal processing circuit 112, the horizontal drive circuit 113, and the like on the basis of the variety of timing signals generated by the timing generator.

The input/output terminal 116 exchanges signals with the outside.

### Application Example 2

The above-described imaging device 100 or the like is applicable, for example, to any type of electronic apparatus with an imaging function including a camera system such as a digital still camera and a video camera, a mobile phone having an imaging function, and the like. FIG. 16 illustrates an outline configuration of an electronic apparatus 1000.

The electronic apparatus 1000 includes, for example, a lens group 1001, the imaging device 100, a DSP (Digital Signal Processor) circuit 1002, a frame memory 1003, a display unit 1004, a recording unit 1005, an operation unit 1006, and a power source unit 1007. They are coupled to each other via a bus line 1008.

The lens group 1001 takes in incident light (image light) from a subject, and forms an image on an imaging surface of the imaging device 100. The imaging device 100 converts the amount of incident light formed as an image on the imaging surface by the lens group 1001 into electric signals in units of pixels, and supplies the DSP circuit 1002 with the electric signals as pixel signals.

The DSP circuit 1002 is a signal processing circuit that processes a signal supplied from the imaging device 100. The DSP circuit 1002 outputs image data obtained by processing the signal from the imaging device 100. The frame memory 1003 temporarily holds the image data processed by the DSP circuit 1002 in units of frames.

The display unit 1004 includes, for example, a panel-type display device such as a liquid crystal panel or an organic EL (Electro Luminescence) panel, and records image data of a moving image or a still image captured by the imaging device 100 in a recording medium such as a semiconductor memory or a hard disk.

The operation unit 1006 outputs an operation signal for a variety of functions of the electronic apparatus 1000 in accordance with an operation by a user. The power source unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to In-Vivo Information Acquisition System

Further, the technology according to an embodiment of the present disclosure (present technology) is applicable to various products. For example, the technology according to an embodiment of the present disclosure may be applied to an endoscopic surgery system.

FIG. 17 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 17, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The description has been given above of one example of the in-vivo information acquisition system, to which the technology according to an embodiment of the present disclosure is applicable. The technology according to an embodiment of the present disclosure is applicable to, for example, the image pickup unit 10112 of the configurations described above. This makes it possible to improve detection accuracy.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

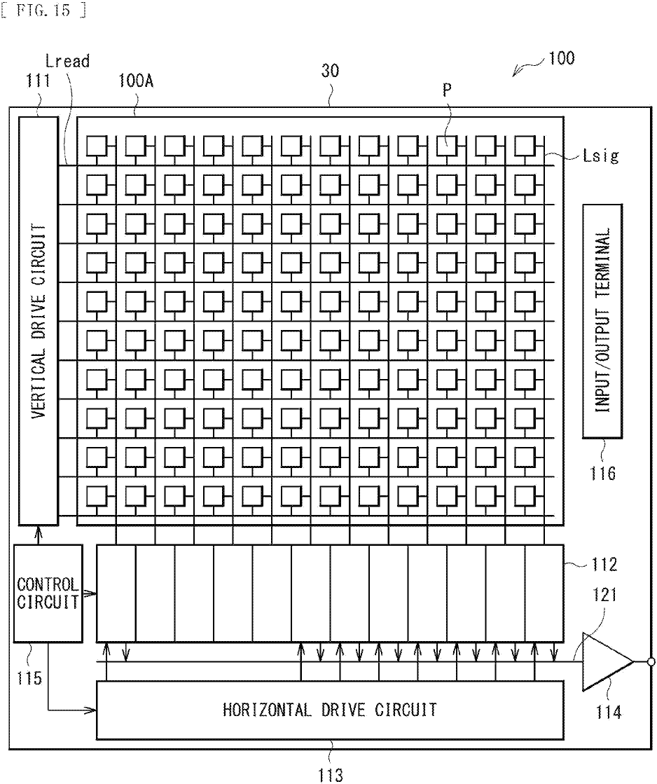

FIG. 18 is a view depicting an example of a schematic configuration of an endoscopic surgery system to which the technology according to an embodiment of the present disclosure (present technology) can be applied.

In FIG. 18, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

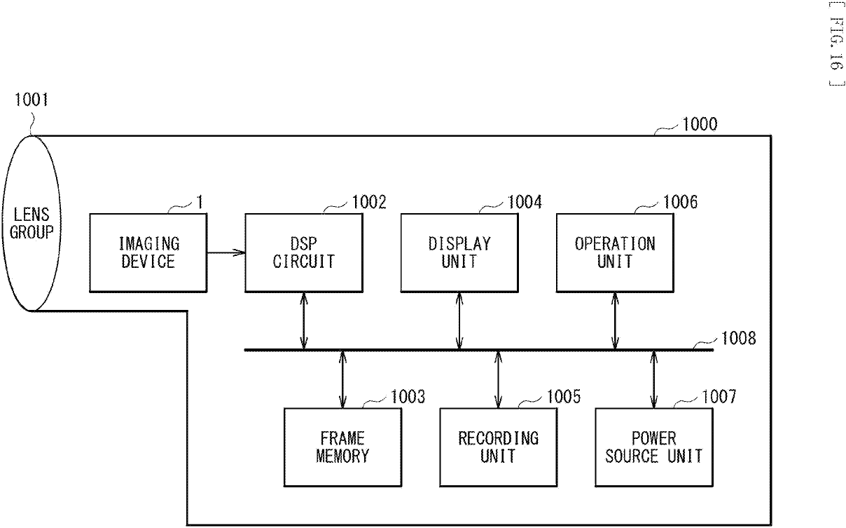

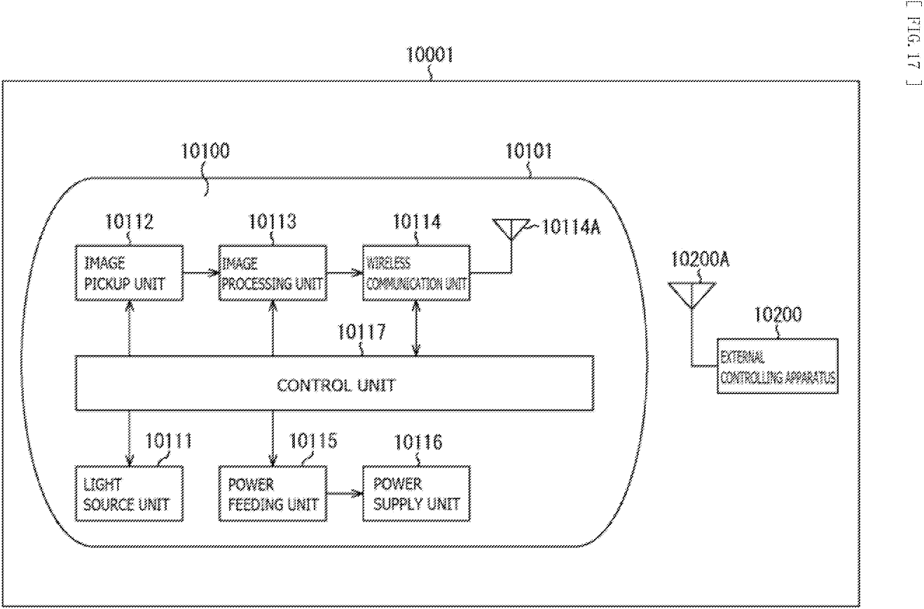

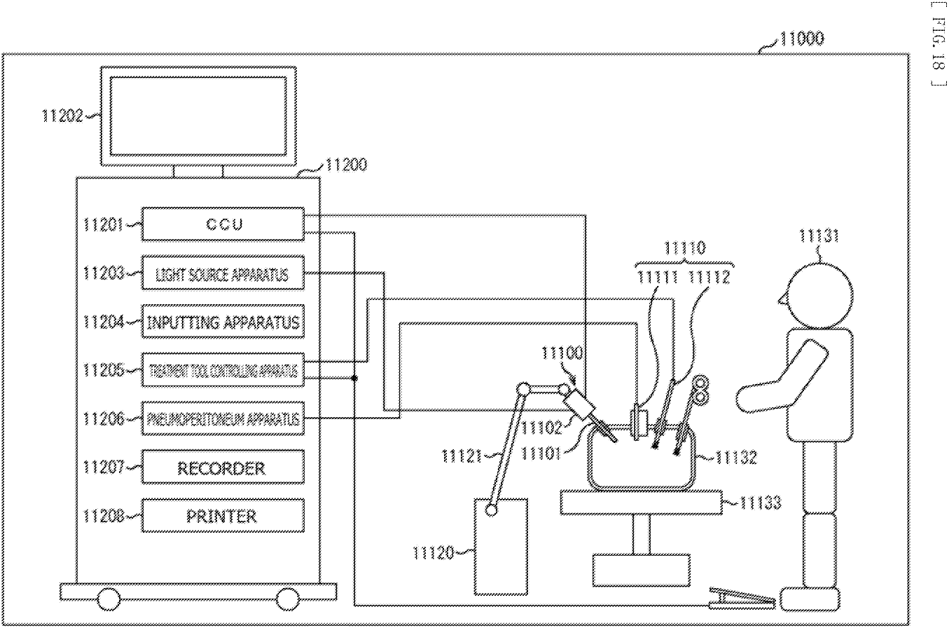

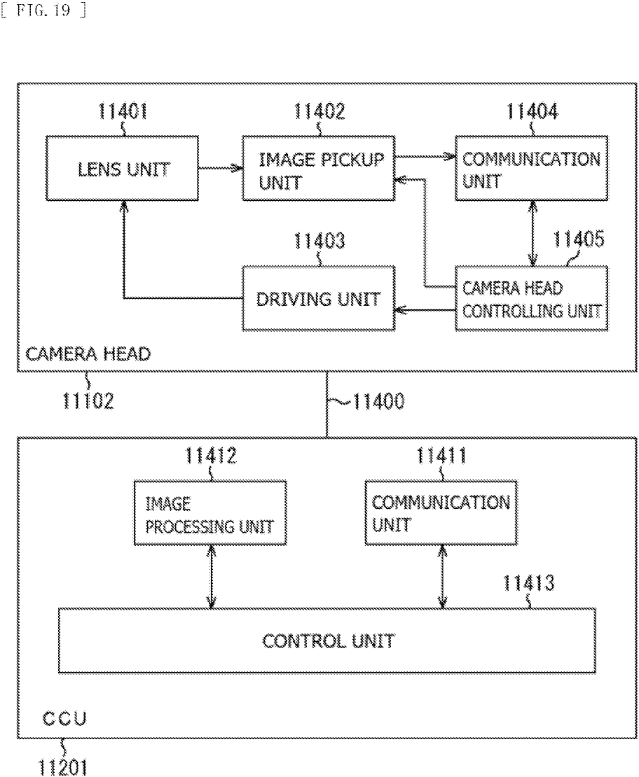

FIG. 19 is a block diagram depicting an example of a functional configuration of the camera head 11102 and the CCU 11201 depicted in FIG. 18.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### Example of Practical Application to Mobile Body

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird’s-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

### 5. Examples

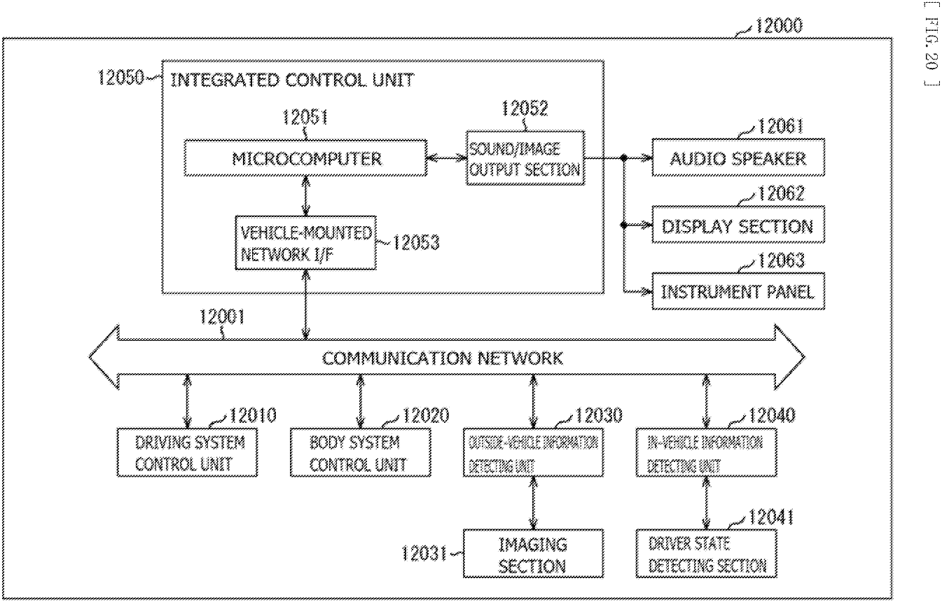

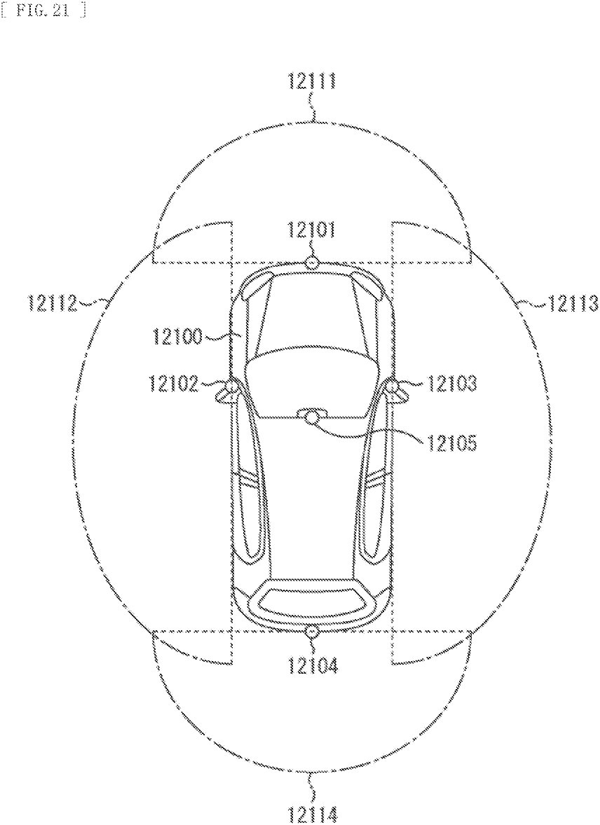

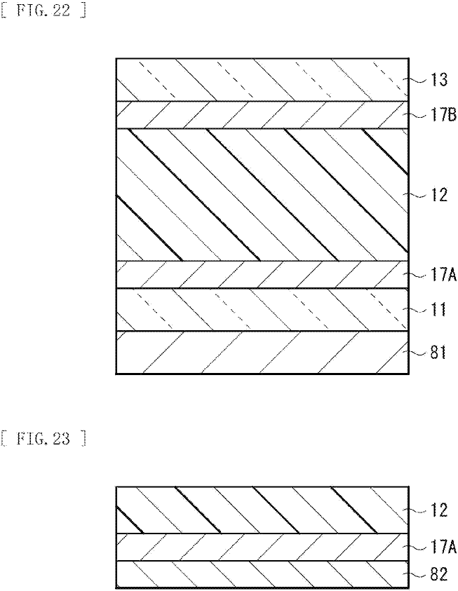

Next, description is given in detail of Examples of the present disclosure. In the present Example, a device sample having a cross-sectional configuration illustrated in FIG. 22 and a domain confirmation sample having a cross-sectional configuration illustrated in FIG. 23 were prepared to evaluate a domain size, a domain cycle, and response characteristics.

### Experimental Example 1

First, an Si substrate 81 provided with an ITO electrode (lower electrode 11) having a thickness of 50 nm was cleaned using UV/ozone treatment. Thereafter, a resistive heating method was used while rotating a substrate holder at a substrate stage temperature of 25° C. under a vacuum of 1 × 10⁻⁵ Pa or less to form a buffer layer 17A having a thickness of 5 nm, the organic photoelectric conversion layer 12 having a thickness of 150 nm, and a buffer layer 18B having a thickness of 5 nm in this order. Subsequently, ITO was formed as the upper electrode 13 to have a thickness of 100 nm by sputtering, and then subjected to heating treatment at 120° C. It is to be noted that the composition ratio between the hole-transporting material and the electron-transporting material constituting the organic photoelectric conversion layer 12 was set to 2:1. As described above, the device samples having a photoelectric conversion region of 1 mm × 1 mm was prepared.

In addition, a similar method was used to form an amorphous carbon 82 having a thickness of 5 nm, the buffer layer 17A having a thickness of 5 nm, and the organic photoelectric conversion layer 12 having a thickness of 10 nm in this order, which were then subjected to heating treatment at 120° C. to prepare a domain observation sample.

### Experimental Example 2

In Experimental Example 2, a device sample and a domain observation sample were prepared using a method similar to that in Experimental Example 1 except that the substrate stage temperature was set to 35° C.

### Experimental Example 3

In Experimental Example 3, a device sample and a domain observation sample were prepared using a method similar to that in Experimental Example 1, except that the substrate stage temperature was set to 45° C., the composition ratio between the hole-transporting material and the electron-transporting material constituting the organic photoelectric conversion layer 12 was set to 2:3, and the heating treatment temperature was set to 150° C.

### Comparison Between Device Sample and Domain Observation Sample

Comparison in a domain distribution between the device sample and the domain observation sample was confirmed as follows.

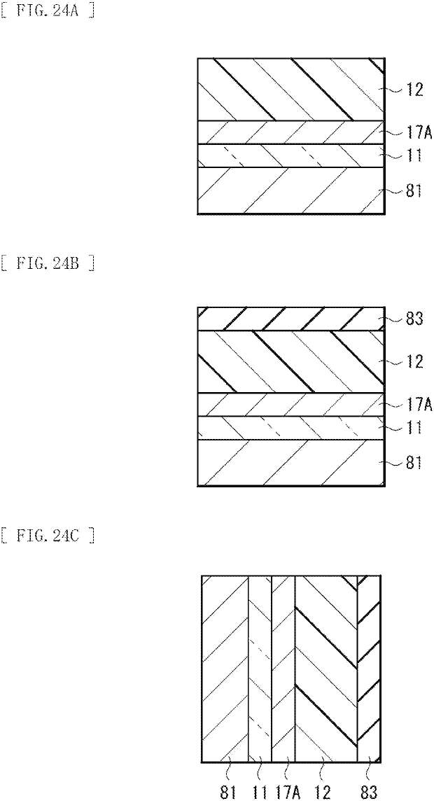

As for the device sample, as illustrated in FIG. 24A, first, film formation was performed up to the lower electrode 11, the buffer layer 17A, and the organic photoelectric conversion layer 12 on the Si substrate 81, and then osmium tetraoxide staining was performed. Thereafter, as illustrated in FIG. 24B, a protective film 83 for preventing damage upon sampling was formed on the organic photoelectric conversion layer 12. After sampling, as illustrated in FIG. 24C, the sample was rotated by 90°, and supported on a TEM observation grid. Thereafter, focused ion beam (Focused Ion Beam; FIB, HELIOS NANOLAB 400S manufactured by FEI Company) was used to work and remove regions A1 and A2 illustrated in FIG. 25. FIGS. 26 and 27 illustrate the working procedures. First, the samples were rotated by about 52°, and the protective film 83 was worked using the FIB in an arrow (solid line) direction. Subsequently, the lower electrode 11 and buffer layer 17A were worked using the FIB in an arrow (broken line) direction to allow a region B to be a thin film of only the organic photoelectric conversion layer 12 as illustrated in FIG. 27, and the thin film was set as a flake sample 1. Further, a layer damaged by the FIB working was removed by an argon ion beam.

As for the domain observation sample, film formation was performed up to the organic photoelectric conversion layer 12 illustrated in FIG. 23, and then osmium tetraoxide staining was performed to obtain a flake sample 2.

HAADF-STEM images of the flake samples 1 and 2 obtained by the above-described steps were observed. A region reflected in black contrast in the HAADF-STEM image is a crystal domain, and a region reflected in white contrast is a stained amorphous domain. In the flake samples 1 and 2, the numbers of crystal domains confirmed in a square region with each side being 100 nm were 33 and 34, respectively, and were confirmed to be substantially equal to each other.

### Evaluation of Domain Size and Domain Cycle

Domain size was measured using XRD as follows. First, the domain observation sample was used to perform measurement by means of a thin-film method using a Cu-Kα ray and a divergence slit of 1 mm. No light-receiving slit was used because of weak diffraction intensity of the organic photoelectric conversion layer 12. Under such a condition, the full width at half maximum FWHM of a diffraction peak derived from a measured organic crystal was measured; in a case where the FWHM thereof was 0.015 rad or more, favorable response characteristics were obtained. The value of the FWHM also varies depending on diffraction angles and on presence or absence of the light-receiving slit; converted crystallite size at 0.015 rad was about 10 nm.

As for the domain cycle, analysis software attached to an electron microscope was used to determine autocorrelation of the HAADF-STEM image, and a distance to be the local maximum value was defined as an average cycle of the domain.

### Evaluation of Response Characteristics

Response characteristics of Experimental Examples 1 to 3 were evaluated. The response characteristics were evaluated by measuring a rate at which a bright current value observed at the time of light irradiation fell after the light irradiation was stopped using a semiconductor parameter analyzer. Specifically, the amount of light to be irradiated from a light source to the photoelectric conversion element via a filter was set to 1.62 µW/cm², and a bias voltage to be applied between the electrodes was set to -2.6 V. After a steady current was observed in this state, the light irradiation was stopped and the current was observed to decay. Subsequently, an area surrounded by a current-time curve and the dark current was set to 100%, and time until the area corresponds to 3% was used as an index of responsiveness. All the evaluations were made at room temperature.

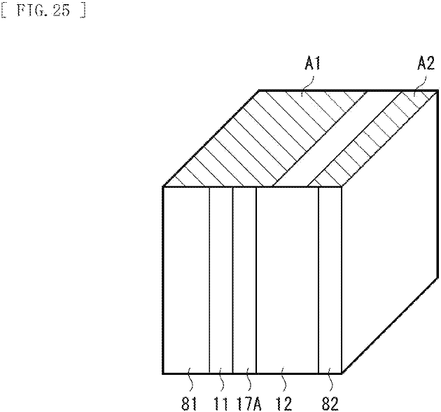

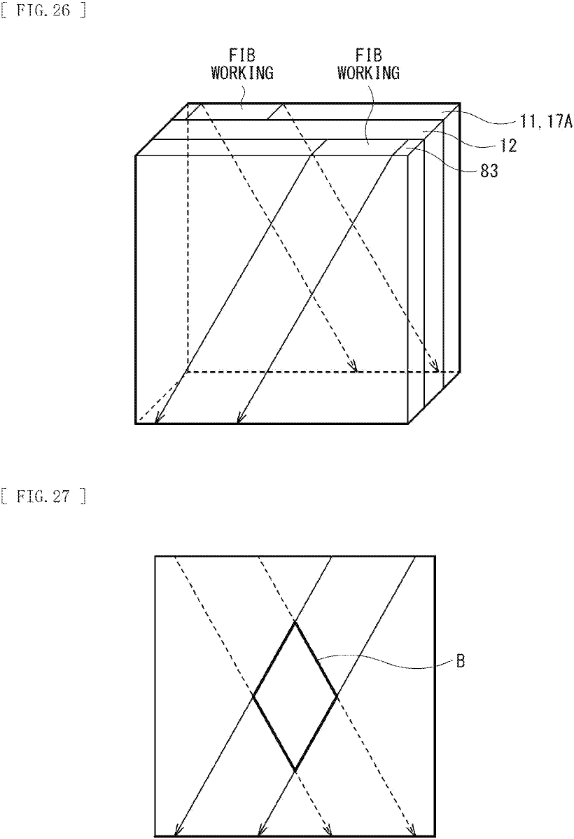

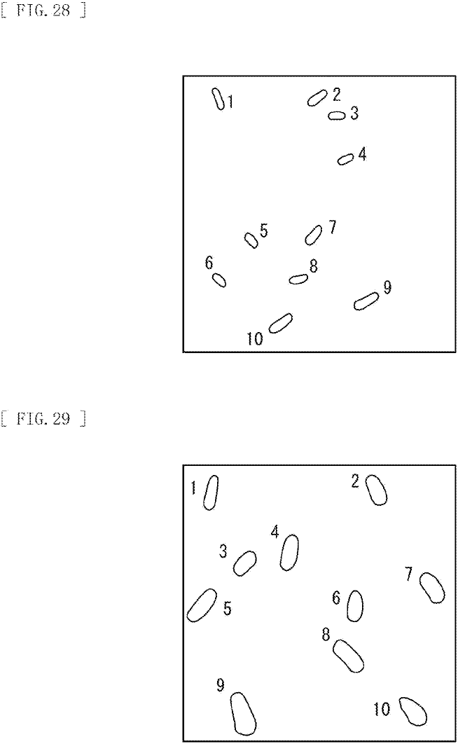

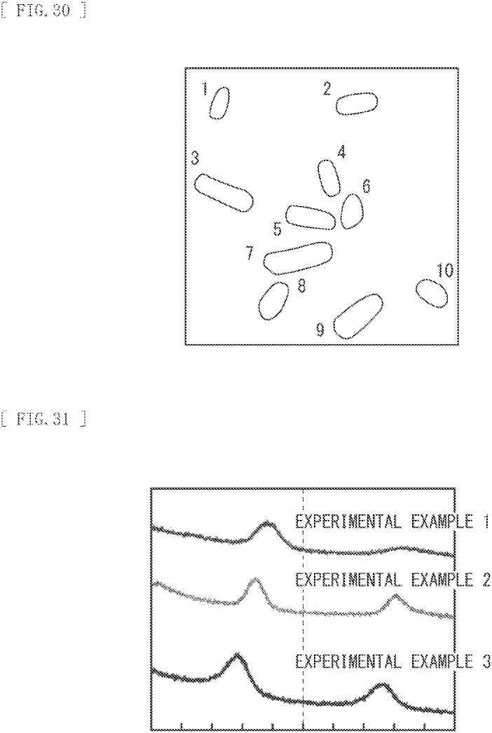

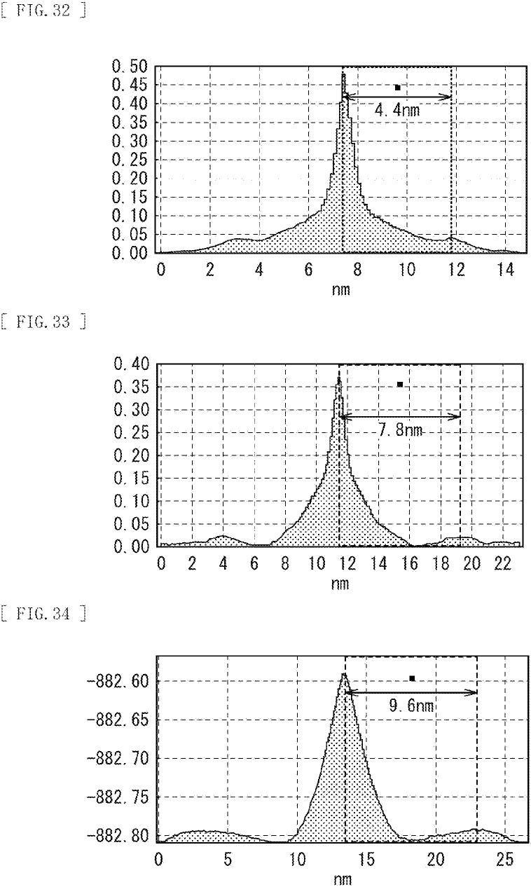

Table 1 summarizes a composition ratio between the hole-transporting material and the electron-transporting material constituting each of the organic photoelectric conversion layers 12 formed as Experimental Examples 1 to 3, a film-forming substrate temperature, a heating treatment temperature, a domain size, a domain cycle, relative time at which a current value after light irradiation OFF is reduced to 1/25, and a relative current at 10 ms after the irradiation OFF. FIGS. 28 to 30 schematically illustrate TEM images of Experimental Examples 1 to 3. FIG. 31 illustrates results of X-ray diffraction of Experimental Examples 1 to 3. FIGS. 32 to 34 illustrate average distances (average cycles) between crystal domains in Experimental Examples 1 to 3.

TABLE 1

| | Crystal: Amorphous | Film-Forming Substrate Temperature (°C) | Heating Treatment Temperature (°C) | Domain Size (nm) | Domain Cycle (nm) | Relative Time at which Current Value after Light Irradiation OFF Is Reduced to 1/25 | Relative Current at 10 ms after Light Irradiation OFF |
|---|---|---|---|---|---|---|---|
| Experimental Example 1 | 2:1 | 25 | 120 | 3 | 4 | 0.05 | 0.1 |
| Experimental Example 2 | 2:1 | 35 | 120 | 6 | 8 | 0.1 | 0.2 |
| Experimental Example 3 | 2:3 | 45 | 150 | 8 | 10 | 1 | 1 |

It is appreciated from Table 1 that a smaller domain size and a smaller domain cycle allow the response characteristics to be improved.

Description has been given hereinabove referring to the embodiment, Modification Examples 1 to 4, and Examples; however, the content of the present disclosure is not limited to the foregoing embodiment and the like, and may be modified in a wide variety of ways. For example, in the foregoing embodiment, the photoelectric conversion element has a configuration in which the organic photoelectric conversion section 10 that detects green light, and the inorganic photoelectric conversion section 32B and the inorganic photoelectric conversion section 32R that detect, respectively, blue light and red light are stacked. However, the content of the present disclosure is not limited to such a structure. That is, no limitation is made to visible light; red light or blue light may be detected in the organic photoelectric conversion section, or green light may be detected in the inorganic photoelectric conversion section.

In addition, the numbers of the organic photoelectric conversion section and the inorganic photoelectric conversion section, and the ratio therebetween are not limitative. Two or more organic photoelectric conversion sections may be provided, or color signals of multiple colors may be obtained only by the organic photoelectric conversion sections. Further, no limitation is made to the structure in which the organic photoelectric conversion section and the inorganic photoelectric conversion section are stacked in the vertical direction; they may be arranged side by side along the substrate surface.

Moreover, the foregoing embodiment, and the like exemplify the configuration of the back-illuminated imaging device; however, the content of the present disclosure is also applicable to a front-illuminated imaging device. In addition, the photoelectric conversion element of the present disclosure does not necessarily include all of the components described in the foregoing embodiment, and may include any other layer, conversely.

It is to be noted that the effects described herein are merely exemplary and are not limitative, and may further include other effects.

It is to be noted that the present technology may also have the following configurations. According to the present technology having the following configurations, an organic photoelectric conversion layer having a domain of 1 nm or more and 10 nm or less including one organic semiconductor material is provided in a predetermined cross-section between a first electrode and a second electrode. This improves movement of electric charges having undergone charge separation in the organic photoelectric conversion layer, thus making it possible to improve the response characteristics.
(1) A photoelectric conversion element including:
   a first electrode;
   a second electrode disposed to be opposed to the first electrode; and
   an organic photoelectric conversion layer provided between the first electrode and the second electrode, the organic photoelectric conversion layer having, in the layer, a domain being larger than 1 nm and smaller than 10 nm and including one organic semiconductor material in a predetermined cross-section between the first electrode and the second electrode.
(2) The photoelectric conversion element according to (1), in which
   the domain at least partially has a crystal property, and
   a ratio of the one organic semiconductor material having a crystal structure in the organic photoelectric conversion layer is 20% or more and 70% or less.
(3) The photoelectric conversion element according to (1) or (2), in which a full width at half maximum of a crystal peak of the one organic semiconductor material by X-ray diffraction is 0.015 rad or more and 0.15 rad or less.
(4) The photoelectric conversion element according to any one of (1) to (3), in which an average cycle of the domain determined from autocorrelation of a two-dimensional distribution in the organic photoelectric conversion layer is 3 nm or more and 5 nm or less.
(5) The photoelectric conversion element according to any one of (1) to (4), in which the organic photoelectric conversion layer includes a hole-transporting material and an electron-transporting material.
(6) The photoelectric conversion element according to (5), in which
   the one organic semiconductor material includes the hole-transporting material or the electron-transporting material, or
   the one organic semiconductor material includes both of the hole-transporting material and the electron-transporting material.
(7) The photoelectric conversion element according to (5) or (6), in which the organic photoelectric conversion layer includes, as the hole-transporting material, an organic material having an ionization potential of 6 eV or less.
(8) The photoelectric conversion element according to (7), in which
   the organic material includes carbon atoms, hydrogen atoms, nitrogen atoms, oxygen atoms, and sulfur atoms, and includes 9 or more and 13 or less aromatic rings in an entire molecule,
   the number of the aromatic rings forming a largest condensed ring is 5 or less,
   the number of single bonds linking the aromatic rings is 5 or more and 9 or less, and
   a length of a short side in the entire molecule is 15% or more and 30% or less of a long side.
(9) The photoelectric conversion element according to any one of (5) to (8), in which the organic photoelectric conversion layer includes, as the electron-transporting material, fullerene or a derivative thereof.
(10) The photoelectric conversion element according to any one of (5) to (9), in which the organic photoelectric conversion layer further includes a pigment material having a local maximum absorption wavelength in a visible region (450 nm or more and 750 nm or less).
(11) An imaging device including pixels, the pixels each including one or multiple organic photoelectric conversion sections,
   the one or the multiple organic photoelectric conversion sections including
      a first electrode,
      a second electrode disposed to be opposed to the first electrode, and
      an organic photoelectric conversion layer provided between the first electrode and the second electrode, the organic photoelectric conversion layer having, in the layer, a domain being larger than 1 nm and smaller than 10 nm and including one organic semiconductor material in a predetermined cross-section between the first electrode and the second electrode.
(12) The imaging device according to (11), in which, in each of the pixels, the one or the multiple organic photoelectric conversion sections and one or multiple inorganic photoelectric conversion sections are stacked, the one or the multiple inorganic photoelectric conversion sections performing photoelectric conversion of a wavelength region different from the organic photoelectric conversion section.
(13) The imaging device according to (12), in which
   the inorganic photoelectric conversion section is formed to be embedded in a semiconductor substrate, and
   the organic photoelectric conversion section is formed on a side of a first surface of the semiconductor substrate.
(14) The imaging device according to (13), in which a multilayer wiring layer is formed on a side of a second surface, of the semiconductor substrate, opposite to the side of the first surface.
(15) The imaging device according to (14), in which
   the organic photoelectric conversion section performs photoelectric conversion of green light, and
   the inorganic photoelectric conversion section that performs photoelectric conversion of blue light and the inorganic photoelectric conversion section that performs photoelectric conversion of red light are stacked in the semiconductor substrate.
(16) The imaging device according to any one of (11) to (15), in which, in each of the pixels, the multiple organic photoelectric conversion sections are stacked, the multiple organic photoelectric conversion sections performing photoelectric conversion of wavelength regions different from one another.

This application claims the benefit of Japanese Priority Patent Application JP2020-106510 filed with the Japan Patent Office on Jun. 19, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first electrode;
a second electrode disposed to be opposed to the first electrode; and
an organic photoelectric conversion layer provided between the first electrode and the second electrode, the organic photoelectric conversion layer having, in the layer, a domain being larger than 1 nm and smaller than 10 nm and including one organic semiconductor material in a predetermined cross-section between the first electrode and the second electrode.

2. The photoelectric conversion element according to claim 1, wherein
the domain at least partially has a crystal property, and
a ratio of the one organic semiconductor material having a crystal structure in the organic photoelectric conversion layer is 20% or more and 70% or less.

3. The photoelectric conversion element according to claim 1, wherein a full width at half maximum of a crystal peak of the one organic semiconductor material by X-ray diffraction is 0.015 rad or more and 0.15 rad or less.

4. The photoelectric conversion element according to claim 1, wherein an average cycle of the domain determined from autocorrelation of a two-dimensional distribution in the organic photoelectric conversion layer is 3 nm or more and 5 nm or less.

5. The photoelectric conversion element according to claim 1, wherein the organic photoelectric conversion layer includes a hole-transporting material and an electron-transporting material.

6. The photoelectric conversion element according to claim 5, wherein
the one organic semiconductor material comprises the hole-transporting material or the electron-transporting material, or
the one organic semiconductor material comprises both of the hole-transporting material and the electron-transporting material.

7. The photoelectric conversion element according to claim 5, wherein the organic photoelectric conversion layer includes, as the hole-transporting material, an organic material having an ionization potential of 6 eV or less.

8. The photoelectric conversion element according to claim 7, wherein
the organic material includes carbon atoms, hydrogen atoms, nitrogen atoms, oxygen atoms, and sulfur atoms, and includes 9 or more and 13 or less aromatic rings in an entire molecule,
the number of the aromatic rings forming a largest condensed ring is 5 or less,
the number of single bonds linking the aromatic rings is 5 or more and 9 or less, and
a length of a short side in the entire molecule is 15% or more and 30% or less of a long side.

9. The photoelectric conversion element according to claim 5, wherein the organic photoelectric conversion layer includes, as the electron-transporting material, fullerene or a derivative thereof.

10. The photoelectric conversion element according to claim 5, wherein the organic photoelectric conversion layer further includes a pigment material having a local maximum absorption wavelength in a visible region (450 nm or more and 750 nm or less).

11. An imaging device comprising pixels, the pixels each including one or multiple organic photoelectric conversion sections,
the one or the multiple organic photoelectric conversion sections including
a first electrode,
a second electrode disposed to be opposed to the first electrode, and
an organic photoelectric conversion layer provided between the first electrode and the second electrode, the organic photoelectric conversion layer having, in the layer, a domain being larger than 1 nm and smaller than 10 nm and including one organic semiconductor material in a predetermined cross-section between the first electrode and the second electrode.

12. The imaging device according to claim 11, wherein, in each of the pixels, the one or the multiple organic photoelectric conversion sections and one or multiple inorganic photoelectric conversion sections are stacked, the one or the multiple inorganic photoelectric conversion sections performing photoelectric conversion of a wavelength region different from the organic photoelectric conversion section.

13. The imaging device according to claim 12, wherein
the inorganic photoelectric conversion section is formed to be embedded in a semiconductor substrate, and
the organic photoelectric conversion section is formed on a side of a first surface of the semiconductor substrate.

14. The imaging device according to claim 13, wherein a multilayer wiring layer is formed on a side of a second surface, of the semiconductor substrate, opposite to the side of the first surface.

15. The imaging device according to claim 14, wherein
the organic photoelectric conversion section performs photoelectric conversion of green light, and
the inorganic photoelectric conversion section that performs photoelectric conversion of blue light and the inorganic photoelectric conversion section that performs photoelectric conversion of red light are stacked in the semiconductor substrate.

16. The imaging device according to claim 11, wherein, in each of the pixels, the multiple organic photoelectric conversion sections are stacked, the multiple organic photoelectric conversion sections performing photoelectric conversion of wavelength regions different from one another.
